(19) United States
(12) Patent Application Publication
(10) Pub. No.: US 2016/0005363 A1
(43) Pub. Date: Jan. 7, 2016

(54) DRIVER OUTPUT STAGE

(71) Applicant: QUALCOMM MEMS Technologies, Inc., San Diego, CA (US)

(72) Inventors: Wilhelmus Johannes Robertus Van Lier, San Diego, CA (US); Joseph Peter John Manca, Sunnyvale, CA (US); Vincent Anthony Condito, Santa Clara, CA (US)

(21) Appl. No.: 14/324,930

(22) Filed: Jul. 7, 2014

(51) Int. Cl. G09G 3/34; H03K 3/012

(52) U.S. Cl. CPC G09G 3/3466; H03K 3/012; G09G 2300/0473; G09G 2310/027

(57) ABSTRACT

This disclosure provides systems, methods and apparatus for providing an output voltage to be used in a display device. In one aspect, a circuit may include switches and a digital-to-analog converter (DAC). A charge recycling circuit may include a capacitive voltage divider providing voltage supplies for the switches to select from and provide to the DAC. A storage capacitor may be configured to be coupled one at a time and in parallel with individual capacitors of the capacitive voltage divider. The storage capacitor may store charge that may be reused. Additionally, a data control circuit may provide control signals for the switches and the DAC.

### TECHNICAL FIELD

This disclosure relates to electromechanical systems and devices. More specifically, the disclosure relates to a digital-to-analog converter (DAC) in a driver output stage for an electromechanical system display device, such as an interferometric modulator (IMOD) display.

### DESCRIPTION OF THE RELATED TECHNOLOGY

Electromechanical systems (EMS) include devices having electrical and mechanical elements, actuators, transducers, sensors, optical components such as mirrors and optical films, and electronics. EMS devices or elements can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of EMS device is called an interferometric modulator (IMOD). The term IMOD or interferometric light modulator refers to a device that selectively absorbs and/or reflects light using the principles of optical interference. In some implementations, an IMOD display element may include a pair of conductive plates, one or both of which may be transparent and/or reflective, wholly or in part, and capable of relative motion upon application of an appropriate electrical signal. For example, one plate may include a stationary layer deposited over, on or supported by a substrate and the other plate may include a reflective membrane separated from the stationary layer by an air gap. The position of one plate in relation to another can change the optical interference of light incident on the IMOD display element. IMOD-based display devices have a wide range of applications, and are anticipated to be used in improving existing products and creating new products, especially those with display capabilities.

In some implementations, one of the plates, or movable element, may be positioned based on an application of voltages to one or more electrodes of the IMOD. The voltages to be applied to the one or more electrodes of the IMOD may be provided by a driver circuit. The driver circuit's output stage may include a digital-to-analog converter (DAC). The output stage may also recycle charge.

### SUMMARY

The systems, methods and devices of this disclosure each have several innovative aspects, no single one of which is solely responsible for the desirable attributes disclosed herein.

One innovative aspect of the subject matter described in this disclosure can be implemented in a circuit comprising a control unit having a first output and a second output; a selector unit having an output and a control input, the control input of the selector unit coupled with the first output of the control circuit, the selector circuit capable of providing an output voltage at the output based on the control input of the selector circuit; and a first voltage source selector unit having a control input, a first output, and a second output, the control input of the first voltage source selector unit coupled with the second output of the control unit, the first output of the first voltage source selector unit coupled with the first power supply input of the selector unit, the second output of the first voltage source selector unit coupled with the second power supply input of the selector unit, wherein the first voltage source selector unit is capable of selecting a first voltage source from a plurality of voltage sources to provide to the first output of the first voltage source selector unit and a second voltage source from the plurality of voltage sources to provide to the second output of the first voltage source selector unit based on the control input of the voltage selector.

In some implementations, the selector unit can include a voltage divider with a first node and a second node, the first node coupled with the first voltage source, and the second node coupled with the second voltage source.

In some implementations, the voltage divider is capable of providing a plurality of voltages based on a first voltage associated with the first voltage source and a second voltage associated with the second voltage source, wherein the output voltage provided by the output of the selector unit corresponds to a voltage in the plurality of voltages.

In some implementations, the voltage divider is a resistor voltage divider including a plurality of resistors coupled in series to define nodes, the nodes of the resistor voltage divider capable of providing the plurality of voltages.

In some implementations, the circuit can include a capacitor voltage divider including a plurality of capacitors coupled in series to define nodes, the nodes capable of providing the plurality of voltage sources.

In some implementations, the circuit can include a storage capacitor coupled in parallel with one of the plurality of capacitors in the capacitor voltage divider.

In some implementations, the circuit can include an amplifier having a first input, a second input, an output, a first power supply input, and a second power supply input, the first input of the amplifier coupled with the output of the selector unit, the second input of the amplifier coupled with the output of the amplifier, the first power supply input of the amplifier coupled with the first voltage source, the second power supply input of the amplifier coupled with the second voltage source.

In some implementations, the control unit can include a third output, and the circuit can also include an amplifier having a first input, a second input, an output, a first power supply input, and a second power supply input, the first input of the amplifier coupled with the output of the selector unit, the second input of the amplifier coupled with the output of the amplifier; and a second voltage source selector unit having a control input, a first output, and a second output, the control input of the second voltage source selector unit coupled with the third output of the control circuit, the first output of the second voltage source unit coupled with the first power supply input of the amplifier, the second output of the second voltage source selector unit coupled with the second power supply input of the amplifier, wherein the second voltage source selector unit is capable of providing a third voltage source to the first output and a fourth voltage source to the second output based on the control input of the voltage selector.

In some implementations, the first voltage source can be capable of providing a first voltage, the second voltage source is capable of providing a second voltage, the third voltage source is capable of providing a third voltage, and the fourth voltage source is capable of providing a fourth voltage, the third voltage being higher than the first voltage, and the fourth voltage being lower than the second voltage.

In some implementations, the control unit can be capable of analyzing data, wherein the control unit is capable of providing a first control signal to the control input of the selector unit based on the data, and wherein the control unit is capable of providing a second control signal to the control input of the first voltage selector unit based on the data.

In some implementations, the data can include a first set of bits and a second set of bits, the first set of bits indicating the first voltage source and the second voltage source from the plurality of voltage sources are to be provided at the first output and the second output, respectively, of the first voltage source selector unit, the second set of bits indicating the output voltage to be provided at the output of the selector unit.

Another innovative aspect of the subject matter described in this disclosure can be implemented in a circuit comprising a control unit capable of receiving data and providing a voltage source determination and a voltage selection determination, the determinations based on the data; a voltage source selector unit capable of selecting a first voltage source and a second voltage source from a plurality of voltage sources based on the voltage source determination; a voltage divider capable of providing a plurality of voltages based on the first voltage source and the second voltage source; and a digital-to-analog converter (DAC) capable of providing an output voltage corresponding to one of the plurality of voltages based on the voltage selection determination.

In some implementations, the circuit can include a capacitor voltage divider including a plurality of capacitors coupled in series to define nodes, the nodes capable of providing the plurality of voltage sources; and a storage capacitor coupled in parallel with one of the plurality of capacitors in the capacitor voltage divider.

In some implementations, the circuit can include an amplifier capable of providing an output voltage based on the output voltage of the DAC.

In some implementations, the control unit can be capable of providing an amplifier voltage source determination based on the data.

In some implementations, the output voltage can be provided to a display unit.

Another innovative aspect of the subject matter described in this disclosure can be implemented in a method comprising determining a first voltage source, a second voltage source, and a voltage input selection, the determination of the first voltage source, the second voltage source, and the voltage input selection based on data indicating a voltage; selecting the first voltage source and the second voltage source; providing a plurality of voltages based on the first voltage source and the second voltage source; and providing an output voltage corresponding to one of the plurality of voltages based on the voltage input selection.

In some implementations, the plurality of voltages based on the first voltage source and the second voltage source can be provided to a digital-to-analog converter (DAC).

In some implementations, the first voltage source and second voltage source can be further provided to an amplifier.

In some implementations, the method can include determining an offset for voltage sources for an amplifier, the offset indicating a difference between the voltage sources for the amplifier and the first voltage source and the second voltage source; selecting a third voltage source and a fourth voltage source based on the offset; and providing the third voltage source and the fourth voltage source to the amplifier.

Details of one or more implementations of the subject matter described in this disclosure are set forth in the accompanying drawings and the description below. Although the examples provided in this disclosure are primarily described in terms of EMS and MEMS-based displays the concepts provided herein may apply to other types of displays such as liquid crystal displays, organic light-emitting diode (“OLED”) displays, and field emission displays. Other features, aspects, and advantages will become apparent from the description, the drawings and the claims. Note that the relative dimensions of the following figures may not be drawn to scale.

### BRIEF DESCRIPTION OF THE DRAWINGS

FIG. 1 is an isometric view illustration depicting two adjacent interferometric modulator (IMOD) display elements in a series or array of display elements of an IMOD display device.

FIG. 2 is a system block diagram illustrating an electronic device incorporating an IMOD-based display including a three element by three element array of IMOD display elements.

FIGS. 3A and 3B are schematic exploded partial perspective views of a portion of an electromechanical systems (EMS) package including an array of EMS elements and a backplate.

FIG. 4 is an example of a system block diagram illustrating an electronic device incorporating an IMOD-based display.

FIG. 5 is a circuit schematic of an example of a three-terminal IMOD.

FIG. 6A is an example of a system block diagram illustrating an output stage of a driver circuit.

FIG. 6B is an example of a system block diagram illustrating an output stage of a driver circuit with charge recycling.

FIG. 7 is a circuit schematic of an example of the output stage of FIG. 6B.

FIG. 8 is a circuit schematic of an example of a charge recycling unit for an output stage.

FIGS. 9A and 9B are circuit schematics of examples of simplified representations of the charge recycling circuit in FIG. 8.

FIG. 9C is a flow diagram illustrating a method for recycling charge.

FIGS. 10A and 10B are circuit schematics of examples of a charge recycling unit providing voltage sources for an output stage with a DAC.

FIGS. 11A and 11B are circuit schematics of examples of simplified representations of FIGS. 10A and 10B.

FIG. 12 is a flow diagram illustrating a method for providing a voltage.

FIGS. 13A and 13B are circuit schematics of examples of output stages of a driver circuit including an amplifier.

FIG. 14A is a circuit schematic of an example of a simplified representation of FIG. 13A.

FIG. 14B is a circuit schematic of an example of a simplified representation of FIG. 13B.

FIG. 15 is a flow diagram illustrating a method for providing an offset for amplifier power supplies.

FIGS. 16A and 16B are system block diagrams illustrating a display device that includes a plurality of IMOD display elements.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device, apparatus, or system that can be configured to display an image, whether in motion (such as video) or stationary (such as still images), and whether textual, graphical or pictorial. More particularly, it is contemplated that the described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, global positioning system (GPS) receivers/navigators, cameras, digital media players (such as MP3 players), camcorders, game consoles, wrist watches, clocks, calculators, television monitors, flat panel displays, electronic reading devices (e.g., e-readers), computer monitors, auto displays (including odometer and speedometer displays, etc.), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS) applications including microelectromechanical systems (MEMS) applications, as well as non-EMS applications), aesthetic structures (such as display of images on a piece of jewelry or clothing) and a variety of EMS devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

Interferometric modulator (IMOD) displays may include a movable element, such as a mirror, that can be positioned at various points in order to reflect light at a specific wavelength. The movable element may be moved to a particular position based on an application of voltages to electrodes of the IMOD. The voltages provided to the electrodes may be provided by a driver circuit. The voltage range applied to the electrodes may be large, and therefore, high voltage devices may be used to produce voltages within the range needed to position the movable element. However, high voltage devices may require larger device sizes, and therefore, occupy more area on the silicon die than low voltage devices. A driver providing a large voltage range may also increase power requirements.

Some implementations of the subject matter described herein include a digital-to-analog converter (DAC) to provide a voltage to be applied to an electrode of an IMOD. The voltage sources provided to the DAC may be selected from a set of voltage sources to provide a low voltage difference between the high voltage source and the low voltage source. Additionally, the voltage sources may be provided by a charge recycling circuit.

Particular implementations of the subject matter described in this disclosure can be implemented to realize one or more of the following potential advantages. Selecting voltage sources to provide a low voltage difference may allow for low voltage devices to be used, and since low voltage devices generally occupy less area on silicon dice, less area of the silicon die may be used. Additionally, charge recycling may lower power requirements.

An example of a suitable EMS or MEMS device or apparatus, to which the described implementations may apply, is a reflective display device. Reflective display devices can incorporate interferometric modulator (IMOD) display elements that can be implemented to selectively absorb and/or reflect light incident thereon using principles of optical interference. IMOD display elements can include a partial optical absorber, a reflector that is movable with respect to the absorber, and an optical resonant cavity defined between the absorber and the reflector. In some implementations, the reflector can be moved to two or more different positions, which can change the size of the optical resonant cavity and thereby affect the reflectance of the IMOD. The reflectance spectra of IMOD display elements can create fairly broad spectral bands that can be shifted across the visible wavelengths to generate different colors. The position of the spectral band can be adjusted by changing the thickness of the optical resonant cavity. One way of changing the optical resonant cavity is by changing the position of the reflector with respect to the absorber.

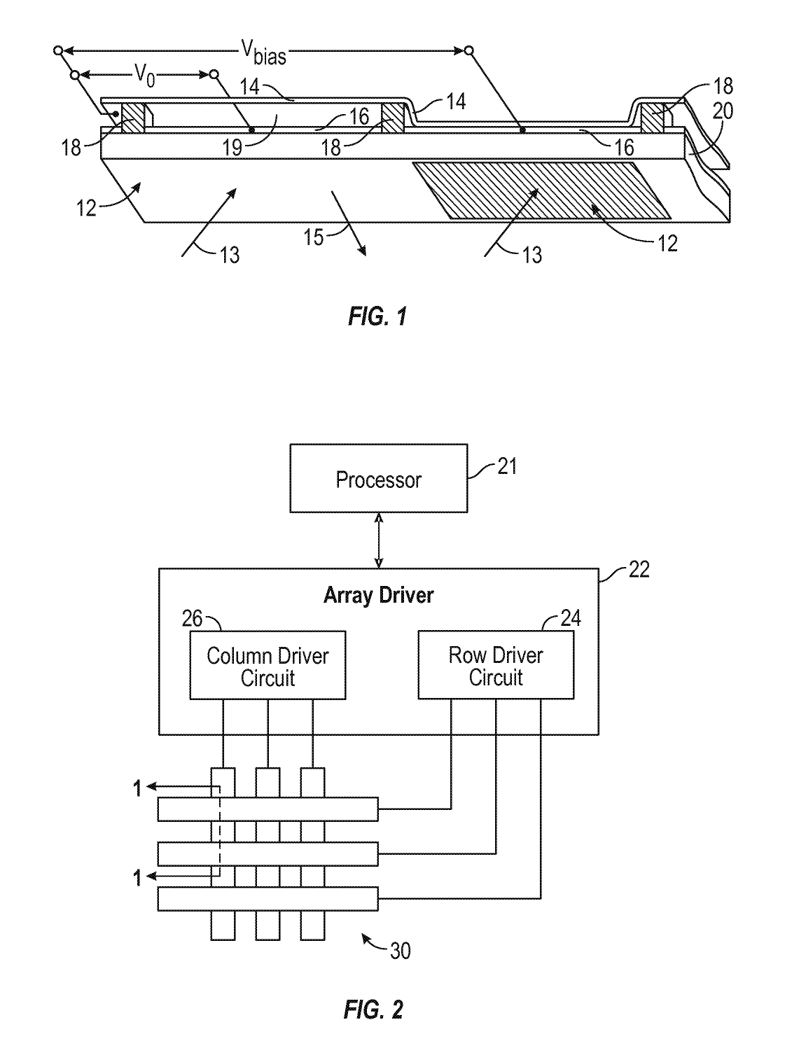

FIG. 1 is an isometric view illustration depicting two adjacent interferometric modulator (IMOD) display elements in a series or array of display elements of an IMOD display device. The IMOD display device includes one or more interferometric EMS, such as MEMS, display elements. In these devices, the interferometric MEMS display elements can be configured in either a bright or dark state. In the bright (“relaxed,” “open” or “on,” etc.) state, the display element reflects a large portion of incident visible light. Conversely, in the dark (“actuated,” “closed” or “off,” etc.) state, the display element reflects little incident visible light. MEMS display elements can be configured to reflect predominantly at particular wavelengths of light allowing for a color display in addition to black and white. In some implementations, by using multiple display elements, different intensities of color primaries and shades of gray can be achieved.

The IMOD display device can include an array of IMOD display elements which may be arranged in rows and columns. Each display element in the array can include at least a pair of reflective and semi-reflective layers, such as a movable reflective layer (i.e., a movable layer, also referred to as a mechanical layer) and a fixed partially reflective layer (i.e., a stationary layer), positioned at a variable and controllable distance from each other to form an air gap (also referred to as an optical gap, cavity or optical resonant cavity). The movable reflective layer may be moved between at least two positions. For example, in a first position, i.e., a relaxed position, the movable reflective layer can be positioned at a distance from the fixed partially reflective layer. In a second position, i.e., an actuated position, the movable reflective layer can be positioned more closely to the partially reflective layer. Incident light that reflects from the two layers can interfere constructively and/or destructively depending on the position of the movable reflective layer and the wavelength(s) of the incident light, producing either an overall reflective or non-reflective state for each display element. In some implementations, the display element may be in a reflective state when unactuated, reflecting light within the visible spectrum, and may be in a dark state when actuated, absorbing and/or destructively interfering light within the visible range. In some other implementations, however, an IMOD display element may be in a dark state when unactuated, and in a reflective state when actuated. In some implementations, the introduction of an applied voltage can drive the display elements to change states. In some other implementations, an applied charge can drive the display elements to change states.

The depicted portion of the array in FIG. 1 includes two adjacent interferometric MEMS display elements in the form of IMOD display elements 12. In the display element 12 on the right (as illustrated), the movable reflective layer 14 is illustrated in an actuated position near, adjacent or touching the optical stack 16. The voltage V_{bias} applied across the display element 12 on the right is sufficient to move and also maintain the movable reflective layer 14 in the actuated position. In the display element 12 on the left (as illustrated), a movable reflective layer 14 is illustrated in a relaxed position at a distance (which may be predetermined based on design parameters) from an optical stack 16, which includes a partially reflective layer. The voltage V₀ applied across the display element 12 on the left is insufficient to cause actuation of the movable reflective layer 14 to an actuated position such as that of the display element 12 on the right.

In FIG. 1, the reflective properties of IMOD display elements 12 are generally illustrated with arrows indicating light 13 incident upon the IMOD display elements 12, and light 15 reflecting from the display element 12 on the left. Most of the light 13 incident upon the display elements 12 may be transmitted through the transparent substrate 20, toward the optical stack 16. A portion of the light incident upon the optical stack 16 may be transmitted through the partially reflective layer of the optical stack 16, and a portion will be reflected back through the transparent substrate 20. The portion of light 13 that is transmitted through the optical stack 16 may be reflected from the movable reflective layer 14, back toward (and through) the transparent substrate 20. Interference (constructive and/or destructive) between the light reflected from the partially reflective layer of the optical stack 16 and the light reflected from the movable reflective layer 14 will determine in part the intensity of wavelength(s) of light 15 reflected from the display element 12 on the viewing or substrate side of the device. In some implementations, the transparent substrate 20 can be a glass substrate (sometimes referred to as a glass plate or panel). The glass substrate may be or include, for example, a borosilicate glass, a soda lime glass, quartz, Pyrex, or other suitable glass material. In some implementations, the glass substrate may have a thickness of 0.3, 0.5 or 0.7 millimeters, although in some implementations the glass substrate can be thicker (such as tens of millimeters) or thinner (such as less than 0.3 millimeters). In some implementations, a non-glass substrate can be used, such as a polycarbonate, acrylic, polyethylene terephthalate (PET) or polyether ether ketone (PEEK) substrate. In such an implementation, the non-glass substrate will likely have a thickness of less than 0.7 millimeters, although the substrate may be thicker depending on the design considerations. In some implementations, a non-transparent substrate, such as a metal foil or stainless steel-based substrate can be used. For example, a reverse-IMOD-based display, which includes a fixed reflective layer and a movable layer which is partially transmissive and partially reflective, may be configured to be viewed from the opposite side of a substrate as the display elements 12 of FIG. 1 and may be supported by a non-transparent substrate.

The optical stack 16 can include a single layer or several layers. The layer(s) can include one or more of an electrode layer, a partially reflective and partially transmissive layer, and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals (e.g., chromium and/or molybdenum), semiconductors, and dielectrics. The partially reflective layer can be formed of one or more layers of materials, and each of the layers can be formed of a single material or a combination of materials. In some implementations, certain portions of the optical stack 16 can include a single semi-transparent thickness of metal or semiconductor which serves as both a partial optical absorber and electrical conductor, while different, electrically more conductive layers or portions (e.g., of the optical stack 16 or of other structures of the display element) can serve to bus signals between IMOD display elements. The optical stack 16 also can include one or more insulating or dielectric layers covering one or more conductive layers or an electrically conductive/partially absorptive layer.

In some implementations, at least some of the layer(s) of the optical stack 16 can be patterned into parallel strips, and may form row electrodes in a display device as described further below. As will be understood by one having ordinary skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of supports, such as the illustrated posts 18, and an intervening sacrificial material located between the posts 18. When the sacrificial material is etched away, a defined gap 19, or optical cavity, can be formed between the movable reflective layer 14 and the optical stack 16. In some implementations, the spacing between posts 18 may be approximately 1-1000 μm, while the gap 19 may be approximately less than 10,000 Angstroms (Å).

In some implementations, each IMOD display element, whether in the actuated or relaxed state, can be considered as a capacitor formed by the fixed and moving reflective layers. When no voltage is applied, the movable reflective layer 14 remains in a mechanically relaxed state, as illustrated by the display element 12 on the left in FIG. 1, with the gap 19 between the movable reflective layer 14 and optical stack 16. However, when a potential difference, i.e., a voltage, is applied to at least one of a selected row and column, the capacitor formed at the intersection of the row and column electrodes at the corresponding display element becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated display element 12 on the right in FIG. 1. The behavior can be the same regardless of the polarity of the applied potential difference. Though a series of display elements in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. In some implementations, the rows may be referred to as “common” lines and the columns may be referred to as “segment” lines, or vice versa. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

FIG. 2 is a system block diagram illustrating an electronic device incorporating an IMOD-based display including a three element by three element array of IMOD display elements. The electronic device includes a processor 21 that may be configured to execute one or more software modules. In addition to executing an operating system, the processor 21 may be configured to execute one or more software applications, including a web browser, a telephone application, an email program, or any other software application.

The processor 21 can be configured to communicate with an array driver 22. The array driver 22 can include a row driver circuit 24 and a column driver circuit 26 that provide signals to, for example a display array or panel 30. The cross section of the IMOD display device illustrated in FIG. 1 is shown by the lines 1-1 in FIG. 2. Although FIG. 2 illustrates a 3×3 array of IMOD display elements for the sake of clarity, the display array 30 may contain a very large number of IMOD display elements, and may have a different number of IMOD display elements in rows than in columns, and vice versa.

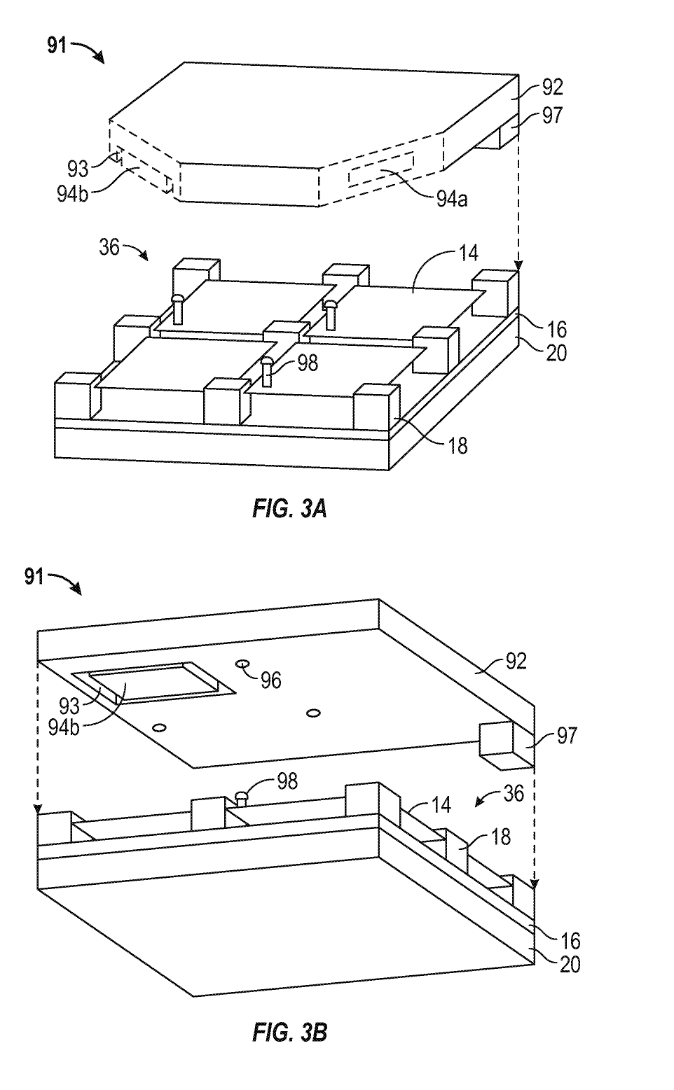

FIG. 3 is a graph illustrating movable reflective layer position versus applied voltage for an IMOD display element. For IMODs, the row/column (i.e., common/segment) write procedure may take advantage of a hysteresis property of the display elements as illustrated in FIG. 3. An IMOD display element may use, in one example implementation, about a 10-volt potential difference to cause the movable reflective layer, or mirror, to change from the relaxed state to the actuated state. When the voltage is reduced from that value, the movable reflective layer maintains its state as the voltage drops back below, in this example, 10 volts, however, the movable reflective layer does not relax completely until the voltage drops below 2 volts. Thus, a range of voltage, approximately 3-7 volts, in the example of FIG. 3, exists where there is a window of applied voltage within which the element is stable in either the relaxed or actuated state. This is referred to herein as the “hysteresis window” or “stability window.” For a display array 30 having the hysteresis characteristics of FIG. 3, the row/column write procedure can be designed to address one or more rows at a time. Thus, in this example, during the addressing of a given row, display elements that are to be actuated in the addressed row can be exposed to a voltage difference of about 10 volts, and display elements that are to be relaxed can be exposed to a voltage difference of near zero volts. After addressing, the display elements can be exposed to a steady state or bias voltage difference of approximately 5 volts in this example, such that they remain in the previously strobed, or written, state. In this example, after being addressed, each display element sees a potential difference within the “stability window” of about 3-7 volts. This hysteresis property feature enables the IMOD display element design to remain stable in either an actuated or relaxed pre-existing state under the same applied voltage conditions. Since each IMOD display element, whether in the actuated or relaxed state, can serve as a capacitor formed by the fixed and moving reflective layers, this stable state can be held at a steady voltage within the hysteresis window without substantially consuming or losing power. Moreover, essentially little or no current flows into the display element if the applied voltage potential remains substantially fixed.

In some implementations, a frame of an image may be created by applying data signals in the form of “segment” voltages along the set of column electrodes, in accordance with the desired change (if any) to the state of the display elements in a given row. Each row of the array can be addressed in turn, such that the frame is written one row at a time. To write the desired data to the display elements in a first row, segment voltages corresponding to the desired state of the display elements in the first row can be applied on the column electrodes, and a first row pulse in the form of a specific “common” voltage or signal can be applied to the first row electrode. The set of segment voltages can then be changed to correspond to the desired change (if any) to the state of the display elements in the second row, and a second common voltage can be applied to the second row electrode. In some implementations, the display elements in the first row are unaffected by the change in the segment voltages applied along the column electrodes, and remain in the state they were set to during the first common voltage row pulse. This process may be repeated for the entire series of rows, or alternatively, columns, in a sequential fashion to produce the image frame. The frames can be refreshed and/or updated with new image data by continually repeating this process at some desired number of frames per second.

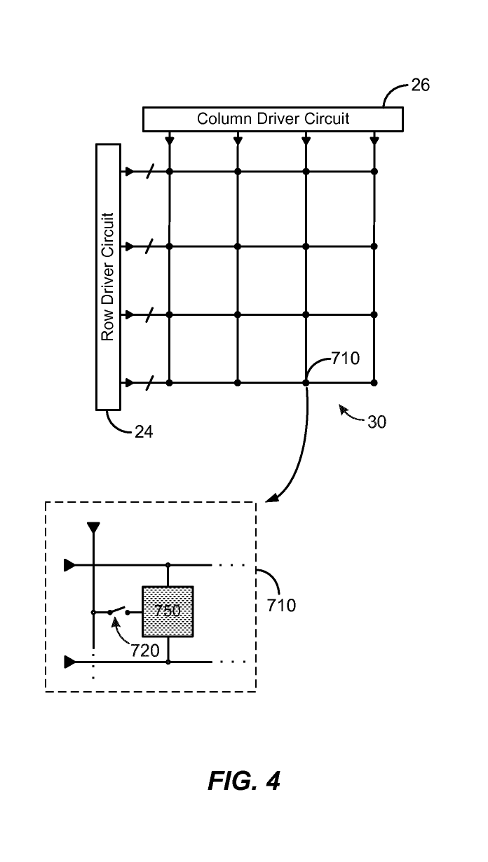

The combination of segment and common signals applied across each display element (that is, the potential difference across each display element or pixel) determines the resulting state of each display element. FIG. 4 is a table illustrating various states of an IMOD display element when various common and segment voltages are applied. As will be readily understood by one having ordinary skill in the art, the “segment” voltages can be applied to either the column electrodes or the row electrodes, and the “common” voltages can be applied to the other of the column electrodes or the row electrodes.

As illustrated in FIG. 4, when a release voltage VC_{REL} is applied along a common line, all IMOD display elements along the common line will be placed in a relaxed state, alternatively referred to as a released or unactuated state, regardless of the voltage applied along the segment lines, i.e., high segment voltage VS_{H} and low segment voltage VS_{L}. In particular, when the release voltage VC_{REL} is applied along a common line, the potential voltage across the modulator display elements or pixels (alternatively referred to as a display element or pixel voltage) can be within the relaxation window (see FIG. 3, also referred to as a release window) both when the high segment voltage VS_{H} and the low segment voltage VS_{L} are applied along the corresponding segment line for that display element.

When a hold voltage is applied on a common line, such as a high hold voltage VC_{HoLD}_{_{—}}_{H} or a low hold voltage VC_{HOLD}_{_{—}}_{L}, the state of the IMOD display element along that common line will remain constant. For example, a relaxed IMOD display element will remain in a relaxed position, and an actuated IMOD display element will remain in an actuated position. The hold voltages can be selected such that the display element voltage will remain within a stability window both when the high segment voltage VS_{H} and the low segment voltage VS_{L} are applied along the corresponding segment line. Thus, the segment voltage swing in this example is the difference between the high VS_{H} and low segment voltage VS_{L}, and is less than the width of either the positive or the negative stability window.

When an addressing, or actuation, voltage is applied on a common line, such as a high addressing voltage VC_{ADD}_{_{—}}_{H} or a low addressing voltage VC_{ADD}_{_{—}}_{L}, data can be selectively written to the modulators along that common line by application of segment voltages along the respective segment lines. The segment voltages may be selected such that actuation is dependent upon the segment voltage applied. When an addressing voltage is applied along a common line, application of one segment voltage will result in a display element voltage within a stability window, causing the display element to remain unactuated. In contrast, application of the other segment voltage will result in a display element voltage beyond the stability window, resulting in actuation of the display element. The particular segment voltage which causes actuation can vary depending upon which addressing voltage is used. In some implementations, when the high addressing voltage VC_{ADD}_{_{—}}_{H} is applied along the common line, application of the high segment voltage VS_{H} can cause a modulator to remain in its current position, while application of the low segment voltage VS_{L} can cause actuation of the modulator. As a corollary, the effect of the segment voltages can be the opposite when a low addressing voltage VC_{ADD}_{_{—}}_{L} is applied, with high segment voltage VS_{H} causing actuation of the modulator, and low segment voltage VS_{L} having substantially no effect (i.e., remaining stable) on the state of the modulator.

In some implementations, hold voltages, address voltages, and segment voltages may be used which produce the same polarity potential difference across the modulators. In some other implementations, signals can be used which alternate the polarity of the potential difference of the modulators from time to time. Alternation of the polarity across the modulators (that is, alternation of the polarity of write procedures) may reduce or inhibit charge accumulation that could occur after repeated write operations of a single polarity.

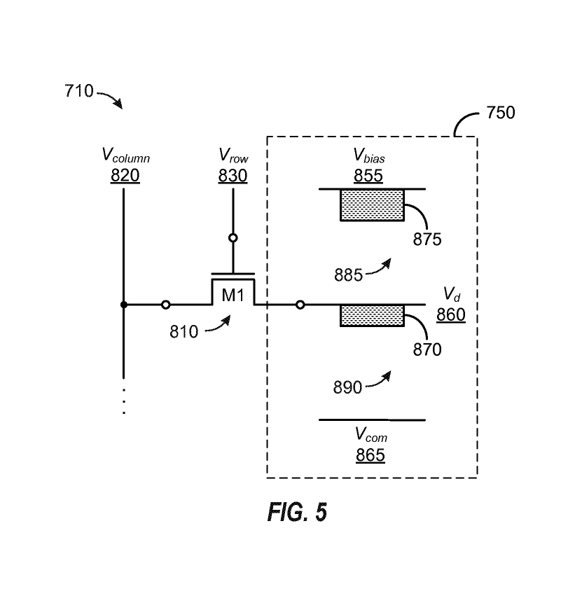

FIG. 5A is an illustration of a frame of display data in a three element by three element array of IMOD display elements displaying an image. FIG. 5B is a timing diagram for common and segment signals that may be used to write data to the display elements illustrated in FIG. 5A. The actuated IMOD display elements in FIG. 5A, shown by darkened checkered patterns, are in a dark-state, i.e., where a substantial portion of the reflected light is outside of the visible spectrum so as to result in a dark appearance to, for example, a viewer. Each of the unactuated IMOD display elements reflect a color corresponding to their interferometric cavity gap heights. Prior to writing the frame illustrated in FIG. 5A, the display elements can be in any state, but the write procedure illustrated in the timing diagram of FIG. 5B presumes that each modulator has been released and resides in an unactuated state before the first line time 60a.

During the first line time 60a: a release voltage 70 is applied on common line 1; the voltage applied on common line 2 begins at a high hold voltage 72 and moves to a release voltage 70; and a low hold voltage 76 is applied along common line 3. Thus, the modulators (common 1, segment 1), (1,2) and (1,3) along common line 1 remain in a relaxed, or unactuated, state for the duration of the first line time 60a, the modulators (2,1), (2,2) and (2,3) along common line 2 will move to a relaxed state, and the modulators (3,1), (3,2) and (3,3) along common line 3 will remain in their previous state. In some implementations, the segment voltages applied along segment lines 1, 2 and 3 will have no effect on the state of the IMOD display elements, as none of common lines 1, 2 or 3 are being exposed to voltage levels causing actuation during line time 60a (i.e., VC_{REL}—relax and VC_{HOLD}_{_{—}}_{L}—stable).

During the second line time 60b, the voltage on common line 1 moves to a high hold voltage 72, and all modulators along common line 1 remain in a relaxed state regardless of the segment voltage applied because no addressing, or actuation, voltage was applied on the common line 1. The modulators along common line 2 remain in a relaxed state due to the application of the release voltage 70, and the modulators (3,1), (3,2) and (3,3) along common line 3 will relax when the voltage along common line 3 moves to a release voltage 70.

During the third line time 60c, common line 1 is addressed by applying a high address voltage 74 on common line 1. Because a low segment voltage 64 is applied along segment lines 1 and 2 during the application of this address voltage, the display element voltage across modulators (1,1) and (1,2) is greater than the high end of the positive stability window (i.e., the voltage differential exceeded a characteristic threshold) of the modulators, and the modulators (1,1) and (1,2) are actuated. Conversely, because a high segment voltage 62 is applied along segment line 3, the display element voltage across modulator (1,3) is less than that of modulators (1,1) and (1,2), and remains within the positive stability window of the modulator; modulator (1,3) thus remains relaxed. Also during line time 60c, the voltage along common line 2 decreases to a low hold voltage 76, and the voltage along common line 3 remains at a release voltage 70, leaving the modulators along common lines 2 and 3 in a relaxed position.

During the fourth line time 60d, the voltage on common line 1 returns to a high hold voltage 72, leaving the modulators along common line 1 in their respective addressed states. The voltage on common line 2 is decreased to a low address voltage 78. Because a high segment voltage 62 is applied along segment line 2, the display element voltage across modulator (2,2) is below the lower end of the negative stability window of the modulator, causing the modulator (2,2) to actuate. Conversely, because a low segment voltage 64 is applied along segment lines 1 and 3, the modulators (2,1) and (2,3) remain in a relaxed position. The voltage on common line 3 increases to a high hold voltage 72, leaving the modulators along common line 3 in a relaxed state. Then, the voltage on common line 2 transitions back to the low hold voltage 76.

Finally, during the fifth line time 60e, the voltage on common line 1 remains at high hold voltage 72, and the voltage on common line 2 remains at the low hold voltage 76, leaving the modulators along common lines 1 and 2 in their respective addressed states. The voltage on common line 3 increases to a high address voltage 74 to address the modulators along common line 3. As a low segment voltage 64 is applied on segment lines 2 and 3, the modulators (3,2) and (3,3) actuate, while the high segment voltage 62 applied along segment line 1 causes modulator (3,1) to remain in a relaxed position. Thus, at the end of the fifth line time 60e, the 3×3 display element array is in the state shown in FIG. 5A, and will remain in that state as long as the hold voltages are applied along the common lines, regardless of variations in the segment voltage which may occur when modulators along other common lines (not shown) are being addressed.

In the timing diagram of FIG. 5B, a given write procedure (i.e., line times 60a-60e) can include the use of either high hold and address voltages, or low hold and address voltages. Once the write procedure has been completed for a given common line (and the common voltage is set to the hold voltage having the same polarity as the actuation voltage), the display element voltage remains within a given stability window, and does not pass through the relaxation window until a release voltage is applied on that common line. Furthermore, as each modulator is released as part of the write procedure prior to addressing the modulator, the actuation time of a modulator, rather than the release time, may determine the line time. Specifically, in implementations in which the release time of a modulator is greater than the actuation time, the release voltage may be applied for longer than a single line time, as depicted in FIG. 5A. In some other implementations, voltages applied along common lines or segment lines may vary to account for variations in the actuation and release voltages of different modulators, such as modulators of different colors.

FIGS. 3A and 3B are schematic exploded partial perspective views of a portion of an EMS package 91 including an array 36 of EMS elements and a backplate 92. FIG. 3A is shown with two corners of the backplate 92 cut away to better illustrate certain portions of the backplate 92, while FIG. 3B is shown without the corners cut away. The EMS array 36 can include a substrate 20, support posts 18, and a movable layer 14. In some implementations, the EMS array 36 can include an array of IMOD display elements with one or more optical stack portions 16 on a transparent substrate, and the movable layer 14 can be implemented as a movable reflective layer.

The backplate 92 can be essentially planar or can have at least one contoured surface (e.g., the backplate 92 can be formed with recesses and/or protrusions). The backplate 92 may be made of any suitable material, whether transparent or opaque, conductive or insulating. Suitable materials for the backplate 92 include, but are not limited to, glass, plastic, ceramics, polymers, laminates, metals, metal foils, Kovar and plated Kovar.

As shown in FIGS. 3A and 3B, the backplate 92 can include one or more backplate components 94a and 94b, which can be partially or wholly embedded in the backplate 92. As can be seen in FIG. 3A, backplate component 94a is embedded in the backplate 92. As can be seen in FIGS. 3A and 3B, backplate component 94b is disposed within a recess 93 formed in a surface of the backplate 92. In some implementations, the backplate components 94a and/or 94b can protrude from a surface of the backplate 92. Although backplate component 94b is disposed on the side of the backplate 92 facing the substrate 20, in other implementations, the backplate components can be disposed on the opposite side of the backplate 92.

The backplate components 94a and/or 94b can include one or more active or passive electrical components, such as transistors, capacitors, inductors, resistors, diodes, switches, and/or integrated circuits (ICs) such as a packaged, standard or discrete IC. Other examples of backplate components that can be used in various implementations include antennas, batteries, and sensors such as electrical, touch, optical, or chemical sensors, or thin-film deposited devices.

In some implementations, the backplate components 94a and/or 94b can be in electrical communication with portions of the EMS array 36. Conductive structures such as traces, bumps, posts, or vias may be formed on one or both of the backplate 92 or the substrate 20 and may contact one another or other conductive components to form electrical connections between the EMS array 36 and the backplate components 94a and/or 94b. For example, FIG. 3B includes one or more conductive vias 96 on the backplate 92 which can be aligned with electrical contacts 98 extending upward from the movable layers 14 within the EMS array 36. In some implementations, the backplate 92 also can include one or more insulating layers that electrically insulate the backplate components 94a and/or 94b from other components of the EMS array 36. In some implementations in which the backplate 92 is formed from vapor-permeable materials, an interior surface of backplate 92 can be coated with a vapor barrier (not shown).

The backplate components 94a and 94b can include one or more desiccants which act to absorb any moisture that may enter the EMS package 91. In some implementations, a desiccant (or other moisture absorbing materials, such as a getter) may be provided separately from any other backplate components, for example as a sheet that is mounted to the backplate 92 (or in a recess formed therein) with adhesive. Alternatively, the desiccant may be integrated into the backplate 92. In some other implementations, the desiccant may be applied directly or indirectly over other backplate components, for example by spray-coating, screen printing, or any other suitable method.

In some implementations, the EMS array 36 and/or the backplate 92 can include mechanical standoffs 97 to maintain a distance between the backplate components and the display elements and thereby prevent mechanical interference between those components. In the implementation illustrated in FIGS. 3A and 3B, the mechanical standoffs 97 are formed as posts protruding from the backplate 92 in alignment with the support posts 18 of the EMS array 36. Alternatively or in addition, mechanical standoffs, such as rails or posts, can be provided along the edges of the EMS package 91.

Although not illustrated in FIGS. 3A and 3B, a seal can be provided which partially or completely encircles the EMS array 36. Together with the backplate 92 and the substrate 20, the seal can form a protective cavity enclosing the EMS array 36. The seal may be a semi-hermetic seal, such as a conventional epoxy-based adhesive. In some other implementations, the seal may be a hermetic seal, such as a thin film metal weld or a glass frit. In some other implementations, the seal may include polyisobutylene (PIB), polyurethane, liquid spin-on glass, solder, polymers, plastics, or other materials. In some implementations, a reinforced sealant can be used to form mechanical standoffs.

In alternate implementations, a seal ring may include an extension of either one or both of the backplate 92 or the substrate 20. For example, the seal ring may include a mechanical extension (not shown) of the backplate 92. In some implementations, the seal ring may include a separate member, such as an O-ring or other annular member.

In some implementations, the EMS array 36 and the backplate 92 are separately formed before being attached or coupled together. For example, the edge of the substrate 20 can be attached and sealed to the edge of the backplate 92 as discussed above. Alternatively, the EMS array 36 and the backplate 92 can be formed and joined together as the EMS package 91. In some other implementations, the EMS package 91 can be fabricated in any other suitable manner, such as by forming components of the backplate 92 over the EMS array 36 by deposition.

FIG. 4 is an example of a system block diagram illustrating an electronic device incorporating an IMOD-based display. Moreover, FIG. 4 depicts an implementation of row driver circuit 24 and column driver circuit 26 of array driver 22 that provide signals to display array or panel 30, as previously discussed.

As an example, display module 710 in the fourth row may include switch 720 and display unit 750. Display module 710 may be provided a row signal and a common signal from row driver circuit 24. Display module 710 may also be provided a column signal from column driver circuit 26. The implementation of display module 710 may include a variety of different designs. In some implementations, display unit 750 may be coupled with switch 720, such as a transistor with its gate coupled to the row signal and its drain coupled with the column signal. Each display unit 750 may include an IMOD display element as a pixel.

Some IMODs are three-terminal devices that use a variety of signals. FIG. 5 is a circuit schematic of an example of a three-terminal IMOD. In the example of FIG. 5, the circuit includes display unit 750 (e.g., an IMOD) of FIG. 4. The circuit of FIG. 5 also includes switch 720 of FIG. 4 implemented as an n-type metal oxide semiconductor (NMOS) transistor M1 810. The gate of transistor M1 810 is coupled to V_{row} 830, which may be provided by row driver circuit 24 of FIG. 4. Transistor M1 810 is also coupled to V_{column} 820, which may be provided by column driver circuit 26 of FIG. 4. If V_{row} 830 is biased to turn transistor M1 810 on, the voltage on V_{column} 820 may be applied to V_{d} electrode 860.

In an implementation, display unit 750 may be a three-terminal IMOD including three terminals or electrodes: V_{bias}, electrode 855, V_{d} electrode 860, and V_{com} electrode 865. Display unit 750 may also include movable element 870 and dielectric 875. Movable element 870 may include a mirror. Movable element 870 may be coupled with V_{d} electrode 860. Additionally, air gap 885 may be between V_{bias} electrode 855 and V_{d} electrode 860. Air gap 890 may be between V_{d} electrode 860 and V_{com} electrode 865. In some implementations, display unit 750 may also include one or more capacitors. For example, one or more capacitors can be coupled between V_{d} electrode 860 and V_{com} electrode 865 or between V_{bias} electrode 855 and V_{d} electrode 860. Additionally, a switch may be coupled between two of the electrodes (e.g., V_{com} electrode 865 and V_{d} electrode 860). When the switch is turned on, the two electrodes are shorted together.

Movable element 870 may be positioned at various points between V_{bias} electrode 855 and V_{com} electrode 865 to reflect light at a specific wavelength. In particular, applied voltage biases of V_{bias} electrode 855, V_{d} electrode 860, and V_{com} electrode 865 may determine the position of movable element 870.

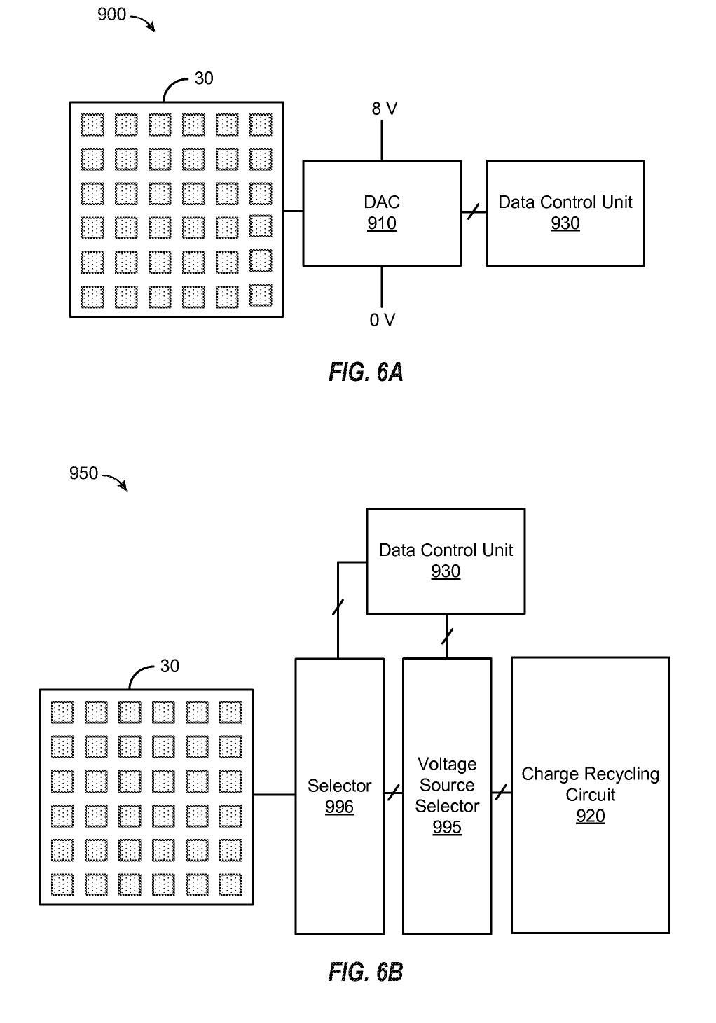

FIG. 6A is an example of a system block diagram illustrating an output stage of a driver circuit. System 900 in FIG. 6A includes digital-to-analog converter (DAC) 910 providing a voltage to be applied to V_{bias} electrode 855, V_{d} electrode 860, and/or V_{com} electrode 865 to position movable element 870. In some implementations, DAC 910 and data control unit 930 may be implemented in row driver circuit 24 and/or column driver circuit 26 of array driver 22.

In FIG. 6A, data control unit 930 may provide data associated with the proper drive voltage to DAC 910, which provides a corresponding voltage to a display unit, such as an IMOD, in display array 30. In particular, DAC 910 may provide a voltage range associated with positioning movable element 870 by biasing an electrode of the display unit. For example, a voltage provided by DAC 910 may be provided to any of V_{bias} electrode 855, V_{d} electrode 860, or V_{com} electrode 865. In FIG. 6A, DAC 910 is provided a high power supply of 8 Volts (V) and a low power supply of 0 V to provide a voltage range of 0 V to 8 V. Accordingly, based on the output of data control unit 930, DAC 910 may drive an electrode of display unit 750 at a voltage between 0 V to 8 V.

However, DAC 910 in FIG. 6A may have high power requirements due to sinking current to the lower power supply. As an example, DAC 925 may provide an output of 8 V. However, when DAC 925 provides a lower voltage, current may sink to the lower power supply (e.g., ground). As such, charge is lost and not reused elsewhere in system 900. Additionally, because DAC 910 has a large difference in voltage between the high power supply and low power supply (e.g., 8 V difference), high voltage devices occupying a large amount of area on the silicon die are used to implement DAC 910 in FIG. 6A.

By contrast, FIG. 6B is an example of a system block diagram illustrating an output stage of a driver circuit with charge recycling to lower power requirements. The output stage of the driver circuit in FIG. 6B may also be able to occupy less area on the silicon die by avoiding the use of high voltage devices.

In FIG. 6B, system 950 includes data control unit 930 providing control signals to selector 996 and voltage source selector 995. Charge recycling circuit 920 may provide voltage sources to voltage source selector 995. Data control unit 930 may receive data and determine the voltage to be provided by selector 996 and applied to V_{bias} electrode 855, V_{d} electrode 860, or V_{com} electrode 865. Based on the data received by data control unit 930, voltage source selector 995 may select voltage sources from charge recycling circuit 920 and provide the voltage sources as power supplies for selector 996. Selector 996 may include a DAC and a voltage divider. The voltage divider may generate a set of voltage inputs for the DAC based on the voltage sources selected by voltage source selector 995. The DAC may select one of the voltage inputs based on the data received by data control unit 930 and provide the selected voltage input to display array 30.

For example, data control unit 930 may receive data indicating that selector 996 is to provide 1.9375 V. Based on the received data, data control unit 930 may provide control signals to voltage source selector 995 and selector 996 to provide 1.9375 V at the output of selector 996. Voltage source selector 995 may select voltage sources (e.g. a voltage source providing 2 V and another voltage source providing 1 V) from a set of voltage sources from charge recycling circuit 920 and provide the voltage sources to selector 996. Selector 996 may use the selected voltage sources to generate a series of voltage inputs (e.g., with a voltage divider) representing voltages between 1 V and 2 V in 62.5 mV increments. Selector 996 may select the voltage input providing 1.9375 V to provide to display array 30 based on the control signals received from data control 930. Accordingly, data control 930 receives data indicating a voltage to be provided by selector 996, generates control signals associated with providing the voltage, voltage source selector 995 selects voltage sources from charge recycling circuit 920, and selector 996 selects an input providing a voltage in a voltage range associated with the selected voltage sources.

In contrast to the implementation of FIG. 6A, system 950 may lower power requirements by recycling charge. For example, if the DAC in selector 996 provides a voltage of 6 V and then switches to provide a voltage of 2 V, charge may be recycled and reused within the system with charge recycling circuit 920, as discussed below. Additionally, because voltage source selector 995 can select voltage sources with a lower voltage difference (e.g., a 1 V difference between two different voltage sources), the use of high voltage devices may be avoided, and therefore, less area on the silicon die may be used by system 950.

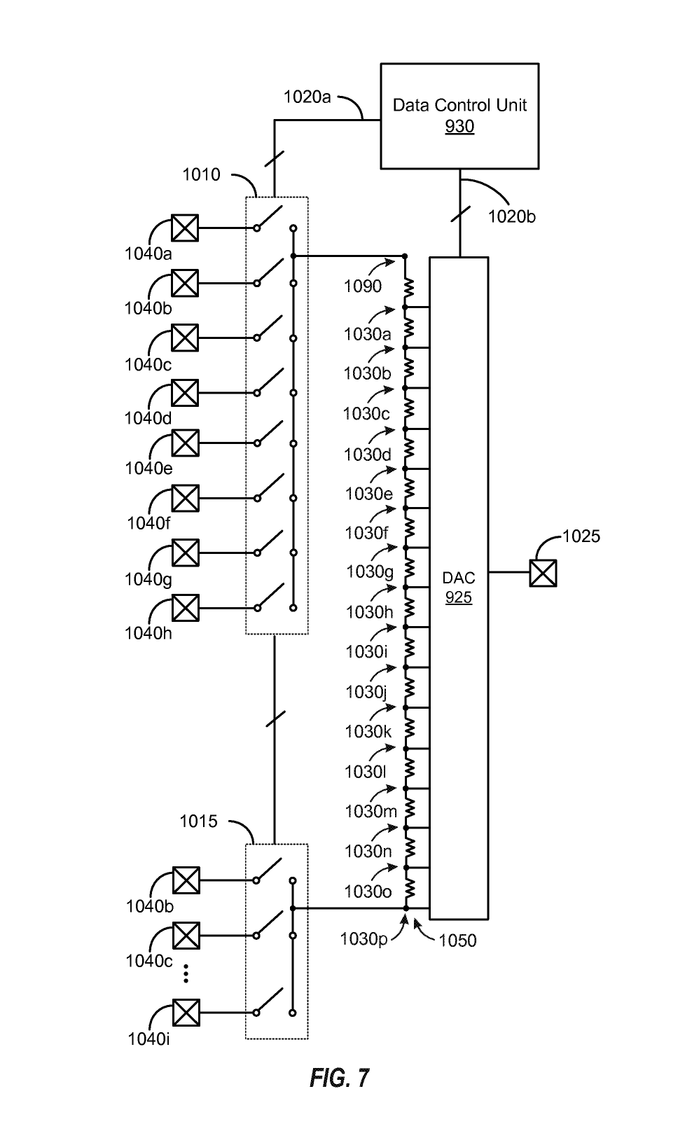

FIG. 7 is a circuit schematic of an example of the output stage of FIG. 6B. In FIG. 7, voltage sources 1040a-1040i may be provided by charge recycling circuit 920. High power supply switches 1010 and low power supply switches 1015 may be provided by voltage source selector 995. String resistor ladder 1050 and DAC 925 may be provided by selector 996. In some implementations, DAC 925 may be a multiplying DAC. DAC 925 may be implemented with switches (e.g., transistors) selected to turn on or off by data control unit 930. String resistor ladder 1050 in FIG. 7 may implement a voltage divider providing sixteen inputs to DAC 925. For example, string resistor ladder 1050 may be implemented as resistors in series and “tapped” with interconnect at nodes 1030a-1030p to provide inputs to DAC 925. Each node among string resistor ladder 1050 may provide a voltage based on the resistances of the resistor segments of string resistor ladder 1050. If each resistor segment in string resistor ladder 1050 has about the same resistance, then each “step down” in the ladder changes the provided voltage in about equal increments. For example, if node 1090 is biased at 1 V, node 1030p is biased at 0 V, and string resistor ladder 1050 provides sixteen inputs to DAC 925, then each step down the nodes in string resistor ladder 1050 decrements the prior node's voltage by 62.5 mV. Accordingly, node 1030a provides a voltage of 937.5 millivolts (mV), or 0.9375 V, as an input to DAC 925. Node 1030b decrements the voltage of the prior node (i.e., node 1030a) by 62.5 mV, and therefore, provides 875 mV. Node 1030c provides another 62.5 mV decrement, and therefore, provides 812.5 mV. Node 1030d decrements by another 62.5 mV from the previous node, node 1030c, and therefore, provides 750 mV. The voltages of the nodes continue to decrement in relatively uniform amounts such that node 1030o provides 62.5 mV and node 1030p provides 0 V.

In some implementations, the resistance of string resistor ladder 1050 may be 300 kilohms (kΩ) to 600 kΩ However, in other implementations, other ranges for the resistance of string resistor ladder 1050 may be used. In some implementations, the resistance of string resistor ladder 1050 may be selected based on the output load capacitance. For example, string resistor ladder 1050 may switch between having a resistance of 300 kΩ or 600 kΩ based on the load capacitance on output 1025. Generally, a larger resistance for string resistor ladder 1050 may be selected to provide lower power requirements while also providing a particular frame rate.

Data control unit 930 may provide control signals 1020b to DAC 925 to select one of nodes 1030a-1030p to provide a voltage at output 1025. In particular, data control unit 930 receives data indicating a voltage to be provided at output 1025 and to a terminal of display unit 750 (e.g., V_{bias} electrode 855, V_{d} electrode 860, and/or V_{com} electrode 865). Based on the data, data control unit 930 provides control signals 1020b to DAC 925 to select one of the inputs provided by nodes 1030a-1030p and provide the voltage to output 1025. For example, if node 1090 is biased at 1 V and node 1030p is biased at 0 V, then node 1030a is biased at 937.5 mV. Data control unit 930 may receive data indicating that a voltage of 937.5 mV is to be provided at output 1025. Accordingly, control signals 1020b generated by data control unit 930 indicate to DAC 925 that the input associated with node 1030a providing 937.5 mV is to be provided at output 1025 (i.e., provide 937.5 mV).

Additionally, data control unit 930 provides control signals 1020a to high power supply switches 1010 and low power supply switches 1015 to provide voltage sources to couple with node 1090 and node 1030p of string resistor ladder 1050. In FIG. 7, high power supply switches 1010 and low power supply switches 1015 may select from voltage sources 1040a-1040i provided by charge recycling circuit 920 to provide voltages at nodes 1090 and 1030p, respectively, of string resistor ladder 1050. In FIG. 7, high power supply switches 1010 may select one of eight voltage sources 1040a-1040h to couple with node 1090 of string resistor ladder 1050. Low power supply switches 1015 may select one of eight voltage sources 1040b-1040i to couple with node 1030p of string resistor ladder 1050. For example, power supply 1040a may provide 8 V, power supply 1040b may provide 7 V, power supply 1040c may provide 6 V, power supply 1040d may provide 5 V, power supply 1040e may provide 4 V, power supply 1040f may provide 3 V, power supply 1040g may provide 2 V, power supply 1040h may provide 1 V, and power supply 1040i may provide 0 V. Accordingly, high power supply switches 1010 select from a voltage source from 1-8 V and low power supply switches 1015 select from a voltage source from 0-7 V. That is, two of nine of voltage source 1040a-1040i may be provided to string resistor ladder 1050, with one of the eight voltage sources with the highest voltages selected to be provided to node 1090 and one of the eight voltage sources with the lowest voltages selected to be provided to node 1030p. In other implementations, high power supply switches 1010 and low power supply switches 1015 may each provide a voltage source from among all of the voltage source. For example, high power supply switches 1010 may select one of voltage source 1040a-1040i. Likewise, low power supply switches 1015 may select one of voltage source 1040a-1040i.

In summary, in the example of FIG. 7, the voltages provided at nodes 1090 and 1030p may determine the voltages at nodes 1030a-1030p because string resistor ladder 1050 provides a voltage divider decrementing the voltages from node 1090 to node 1030p in relatively equal increments. Data control unit 930 may provide control signals 1020a determining which switches in high power supply switches 1010 and low power supply switches 1015 are turned on such that node 1090 and node 1030p are biased at particular voltages. For example, if the switch in high power supply switches 1010 coupled with voltage source 1040a (e.g., 8 V) is turned on and all of the other switches in high power supply switches 1010 are turned off, then 8 V is applied to an input of string resistor ladder 1050 (i.e., node 1090). If the switch in low power supply switches 1015 coupled with voltage source 1040b (e.g., 7 V) is turned on and all of the other switches in low power supply switches 1015 are turned off, then 7 V is applied to node 1030p (i.e., the other input of string resistor ladder 1050). Accordingly, nodes 1030a-1030p may provide voltages in 62.5 mV increments between 7.9375 V and 7 V. As another example, if nodes 1030a-1030p are to provide voltages between 1.9375 V and 1 V in 62.5 mV increments, then the switch in high power supply switches 1010 providing power supply 1040g (e.g., 2 V) is turned on and the switch in low power supply switches 1015 providing power supply 1040h (e.g., 1 V) is turned on. Data control unit 930 also provides control signals 1020b to indicate which voltage corresponding to nodes 1030a-1030p is to be provided at output 1025. Accordingly, data control unit 930 generates control signals 1020a and 1020b which are used to provide a particular voltage at output 1025.

Voltage sources 1040a-1040i selected to be provided to nodes 1090 and 1030p may also be used as power supplies, for example, for DAC 925. Since the voltages provided by voltage sources 1040a-1040i can be selected to provide a low voltage difference (e.g., 1 V difference), DAC 925 may be implemented with smaller low voltage devices, and therefore, save area on the silicon die.

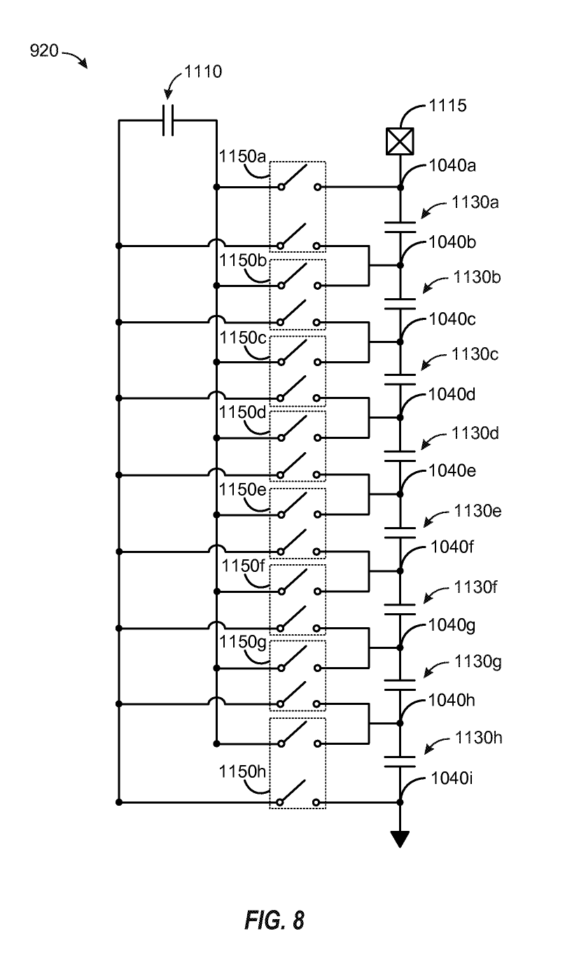

FIG. 8 is a circuit schematic of an example of charge recycling unit 920 for an output stage. In some implementations, the charge recycling unit of FIG. 8 provides voltage sources 1040a-1040i to be used as power supplies for system 950. That is, high power supply switches 1010 and low power supply switches 1015 select from voltage sources 1040a-1040i provided by charge recycling unit 920 to provide voltages at node 1090 of string resistor ladder 1050 and node 1030p of string resistor ladder 1050. Charge recycling unit 920 may provide lower power requirements by recycling charge, as discussed below.

In FIG. 8, capacitors 1130a-1130h may be coupled in series to form a capacitor voltage divider defining a series of nodes providing voltage sources 1040a-1040i. Voltage input 1115 (e.g., from a battery) may provide an 8 V input and voltage source 1040i may be biased to 0 V (e.g., grounded). Accordingly, voltage source 1040a is biased at 8 V and provides a voltage source for high power supply switches 1010 and/or low power supply switches 1015 to select. Based on the capacitances of capacitors 1130a-1130h being similar, voltage sources 1040a-1040i may be used as power supplies in FIG. 7. For example, if voltage source 1040a is biased at 8 V by voltage input 1115 and voltage source 1040i is biased at 0 V, then voltage source 1040a provides 8 V, voltage source 1040b provides 7 V, voltage source 1040c provides 6 V, voltage source 1040d provides 5 V, voltage source 1040e provides 4 V, voltage source 1040f provides 3 V, voltage source 1040g provides 2 V, voltage source 1040h provides 1 V, and voltage source 1040i provides 0 V because the voltage source are nodes between capacitors 1130a-1130h coupled in series. Accordingly, voltage sources 1040a-1040i provide voltages that may be selected by high power supply switches 1010 and low power supply switches 1015.

In addition to providing voltage sources 1040a-1040i, charge recycling circuit 920 may also recycle charge between capacitors 1130a-1130h. In particular, switch pairs 1150a-1150h may turn on one at a time and couple one of capacitors 1130a-1130h in parallel with charge pump capacitor 1110. Charge pump capacitor 1110 may act as a storage capacitor for storing excess charge and replenishing charge among capacitors 1130a-1130h. In some implementations, capacitors 1130a-1130h and charge pump capacitor 1110 may have capacitances from 1 microfarad (μF) to 10 μF. In some implementations, capacitors 1130a-1130h and charge pump capacitor 1110 may have capacitances from 0.1 μF to 10 μF. The preceding ranges for the capacitances are merely examples of ranges. In other implementations, other ranges can be used.

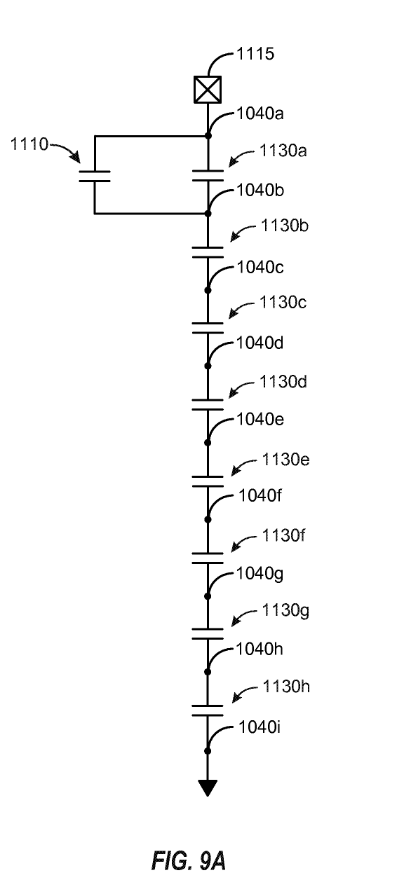

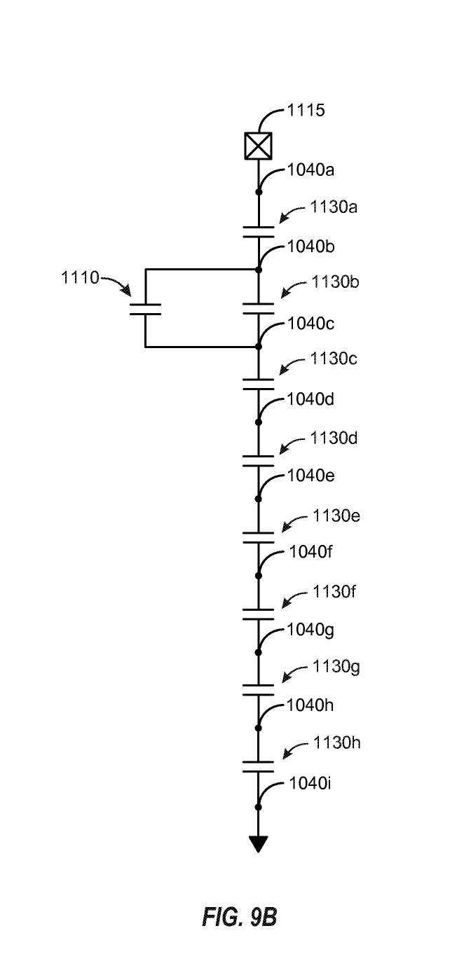

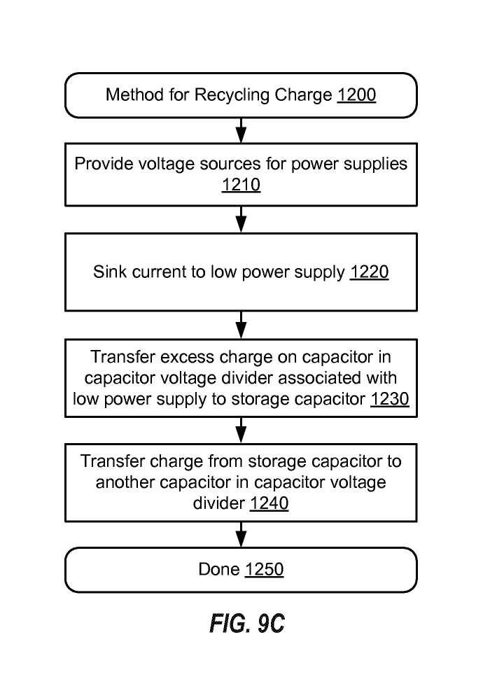

For example, FIGS. 9A and 9B are circuit schematics of examples of simplified representations of the charge recycling circuit in FIG. 8. In FIG. 9A, if the two switches in switch pair 1150a are turned on and the switches in switch pairs 1150b-1150h are turned off, charge pump capacitor 1110 may be coupled in parallel with capacitor 1130a. Likewise, in FIG. 9B, if the two switches in switch pair 1150b are turned on and the switches in switch pairs 1150a and 1150c-1150h are turned off, charge pump capacitor 1110 may be coupled in parallel with capacitor 1130b. Switch pairs 1150c-1150h may also be independently turned on to couple charge pump capacitor 1110 in parallel with capacitors 1130c-1130h.

In some implementations, charge pump capacitor 1110 can be coupled in parallel with more than one of capacitors 1130a-1130h at a time. For example, charge pump capacitor 1110 may be coupled in parallel with two capacitors at a time (e.g., with one terminal of charge pump capacitor 1110 coupled with node 1040a and a second terminal of charge pump capacitor 1110 coupled with node 1040c). When charge pump capacitor 1110 is coupled in parallel with two capacitors at a time, the voltage across charge pump capacitor 1110 would be ¼ of the voltage provided by voltage input 1115 (e.g., a difference of 2 V when voltage input 1115 provides 8 V and each of nodes 1040a-1040i decrements from 8 V to 0 V in 1 V steps) rather than ⅛ of the voltage as in the prior example (e.g., a 1 V difference when voltage input 1115 provides 8 V and each of nodes 1040a-1040i decrements from 8 V to 0 V in 1 V steps).

As an example, the switches in switch pair 1150a may turn on, and therefore, couple charge pump capacitor 1110 in parallel with capacitor 1130a. Next, the switches in switch pair 1150a turn off. Subsequently, the switches in switch pair 1150b turn on, and therefore, couple charge pump capacitor 1110 in parallel with capacitor 1130b. Next, the switches in switch pair 1150b turn off, and therefore, charge pump capacitor 1110 is no longer coupled to any of capacitors 1130a-1130h. Subsequently, the switches in switch pair 1150c turn on, and therefore, couple charge pump capacitor 1110 in parallel with capacitor 1130c. Next, the switches in switch pair 1150c turn off, followed by the switches in switch pair 1150d turning on, and therefore, coupling charge pump capacitor 1110 in parallel with capacitor 1130d. Next, the switches in switch pair 1150d turn off, followed by the switches in switch pair 1150e turning on, and therefore, couple charge pump capacitor 1110 with capacitor 1150e. Likewise, switch pairs 1150f-1150h also turn on and off to allow charge pump capacitor 1110 to cycle through being coupled in parallel with capacitors 1130f-1130h. Charge pump capacitor 1110 may then be coupled again with capacitor 1130a and restart the cycling. Accordingly, the switches in switch pairs 1150a-1150h may be cycled to be turned on and couple charge pump capacitor 1080 in parallel with one of the capacitors 1130a-1130h.

Charge pump capacitor 1110 may store excess charge from capacitors 1130a-1130h when they are coupled in parallel. Additionally, charge pump capacitor 1110 may also recharge capacitors 1130a-1130h when they are coupled in parallel. In general, when charge pump capacitor 1110 is in parallel with one of capacitors 1130a-1130h, charge may flow from the capacitor with higher voltage to the capacitor with lower voltage.

For example, if DAC 925 in FIG. 7 transitions from providing a higher voltage to a lower voltage, charge may sink to voltage source 1040a-1040i coupled with node 1030p (i.e., the voltage source providing the lower voltage to string resistor ladder 1050 and used as a power supply for DAC 925) and to one of capacitors 1130a-1130h coupled with node 1030p. The voltage associated with the capacitor receiving the excess charge may increase. If DAC 925 transitions from a lower voltage to a higher voltage, charge may be used from one of capacitors 1130a-1130h coupled with node 1090. The voltage associated with the capacitor providing the charge may decrease. When a set of switches in switch pair 1150a-1150h turns on, charge pump capacitor 1110 may be coupled in parallel with one of capacitors 1130a-1130h of the capacitive voltage divider, and therefore, excess charge may be transferred to charge pump capacitor 1110 if it has a lower voltage than the capacitor it is coupled in parallel with. Afterwards, when another switch pair 1150a-1150h turns on, charge pump capacitor 1110 may replenish the charge of a capacitor if it has a lower voltage than charge pump capacitor 1110. In some implementations, a switch pair may be configured to be on for a time that allows the respective capacitor to be fully recharged by charge pump capacitor 1110.

Accordingly, charge may be transferred from capacitors 1130a-1130h to charge pump capacitor 1110 to store charge, and transferred from charge pump capacitor 1110 to capacitors 1130a-1130h to replenish charge. As such, charge may be recycled to provide lower power requirements.

FIG. 9C is a flow diagram illustrating a method for recycling charge. In method 1200, at block 1210, voltage sources to be used as power supplies may be provided. For example, high power supply switches 1010 and low power supply switches 1015 may each select one of voltage sources 1040a-1040i. In block 1220, current may sink to the voltage source selected by low power supply switches 1015 and charge may accumulate on one of capacitors 1130a-1130h. For example, if high power supply switches 1010 select voltage source 1040a providing 8 V and low power supply switches 1015 select voltage source 1040b providing 7 V, charge may accumulate on capacitor 1130b if DAC 925 transitions to providing a lower voltage at output 1025. In block 1230, excess charge on a capacitor may be transferred to the storage capacitor. For example, charge pump capacitor 1110 may cycle to be coupled in parallel with capacitors 1130a-1130h. If capacitors 1130a-1130h have excess charge, charge may be transferred to the charge pump capacitor 1110. In block 1240, charge may be transferred from charge pump capacitor 1110 to one of capacitors 1130a-1130h. The method is done at block 1250.

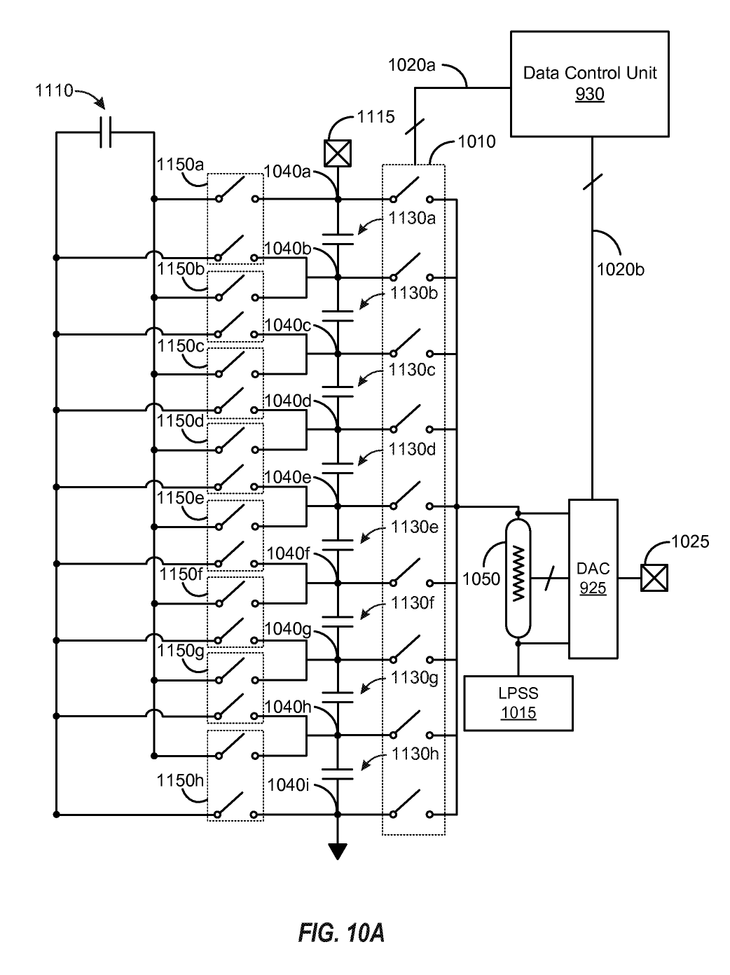

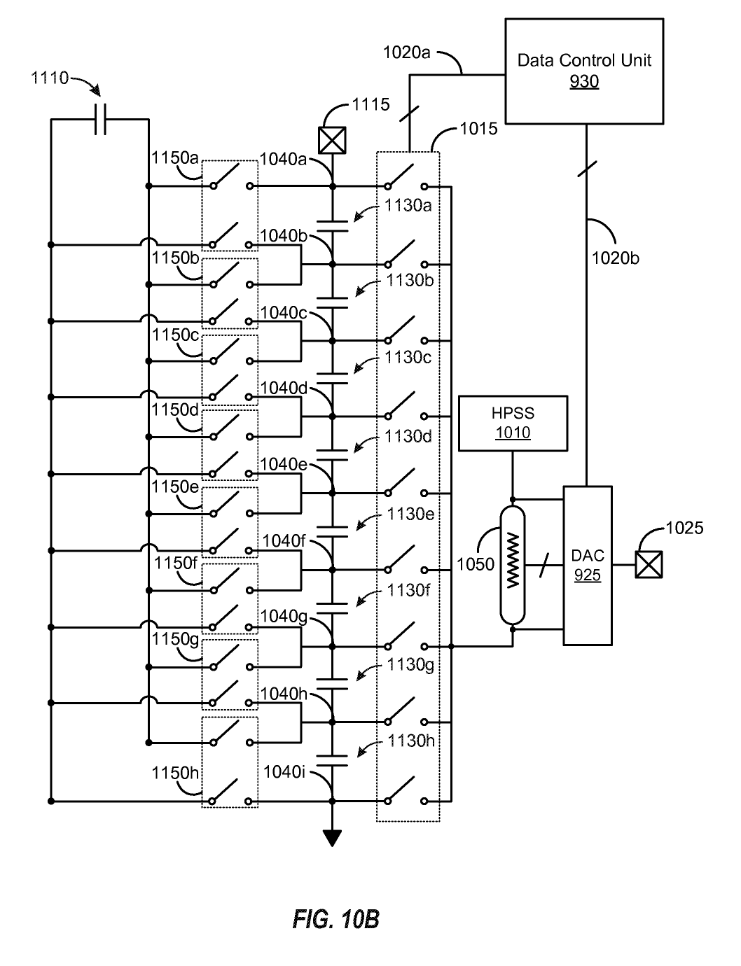

FIGS. 10A and 10B are circuit schematics of examples of a charge recycling unit providing voltage sources for an output stage with a DAC. FIG. 10A shows high power supply switches 1010 coupled with voltage sources 1040a-1040i provided by the capacitive voltage divider composed of capacitors 1130a-1130h. FIG. 10B shows low power supply switches 1015 coupled with voltage sources 1040a-1040i provided by the capacitive voltage divider composed of capacitors 1130a-1130h.

As previously discussed, data control unit 930 may provide control signals 1020a and 1020b to provide a particular voltage at output 1025 of DAC 925. As an example, data control unit 930 may receive 7-bit digital data. The 7-bit data may be decoded to generate control signals 1020a and 1020b. Because charge recycling circuit 920 includes eight capacitors 1130a-1130h, three bits of the 7-bit data indicate which of capacitors 1130a-1130h DAC 925 and string resistor ladder 10150 are coupled in parallel with, and therefore, also indicates which voltage sources 1040a-1040i may be coupled with nodes 1090 and 1030p. Because DAC 925 includes sixteen inputs (i.e., nodes 1030a-1030p), the remaining four bits of the 7-bit data indicate which voltage of nodes 1030a-1030p may be provided at output 1025 of DAC 925. The three bits indicating which of capacitors 1130a-1130h that DAC 925 is to be coupled in parallel with may be the three least significant bits (LSBs) and the four bits indicating which voltage of nodes 1030a-1030p is to be provided at output 1025 may be the four most significant bits (MSBs). Alternatively, the three bits may be the three MSBs and the four bits may be the four LSBs.

As an example, data control unit 930 may receive 7-bit data of “0000000” indicating a voltage of 0 V to be provided to output 1025. The first three bits of the 7-bits (i.e., “000”) may indicate that DAC 925 is to be coupled in parallel with capacitor 1130h by providing control signals 1020a to high power supply switches 1010 and low power supply switches 1015 such that voltage sources 1040h (e.g., providing 1 V) and 1040i (e.g., providing 0 V) are selected. The last four bits of the 7-bits (i.e., “0000”) may indicate that DAC 925 is to select node 1030p (biased at 0 V) to provide a voltage at output 1025.

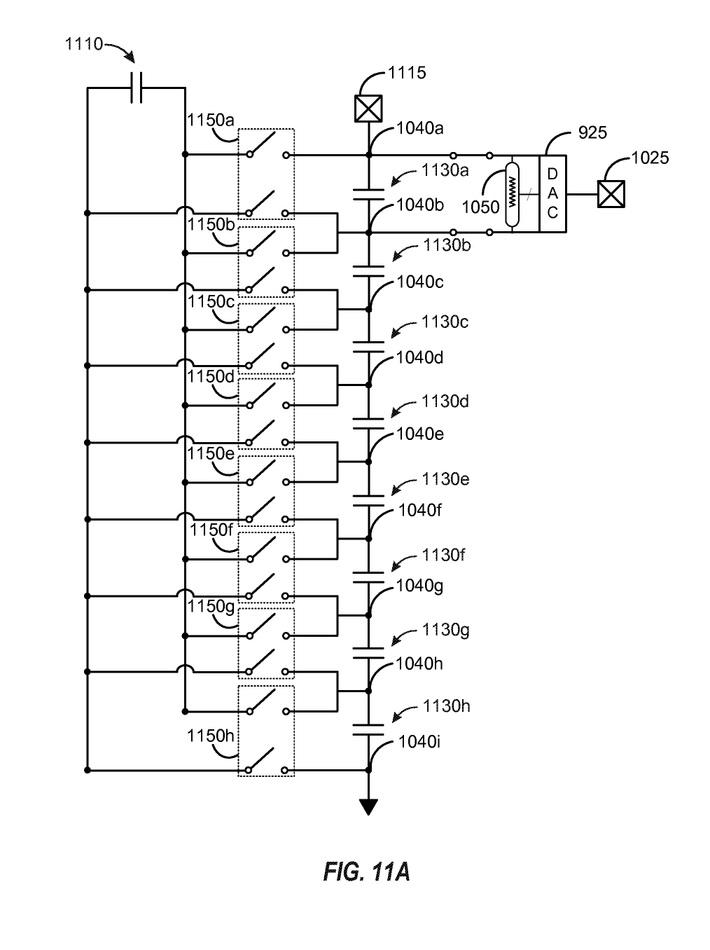

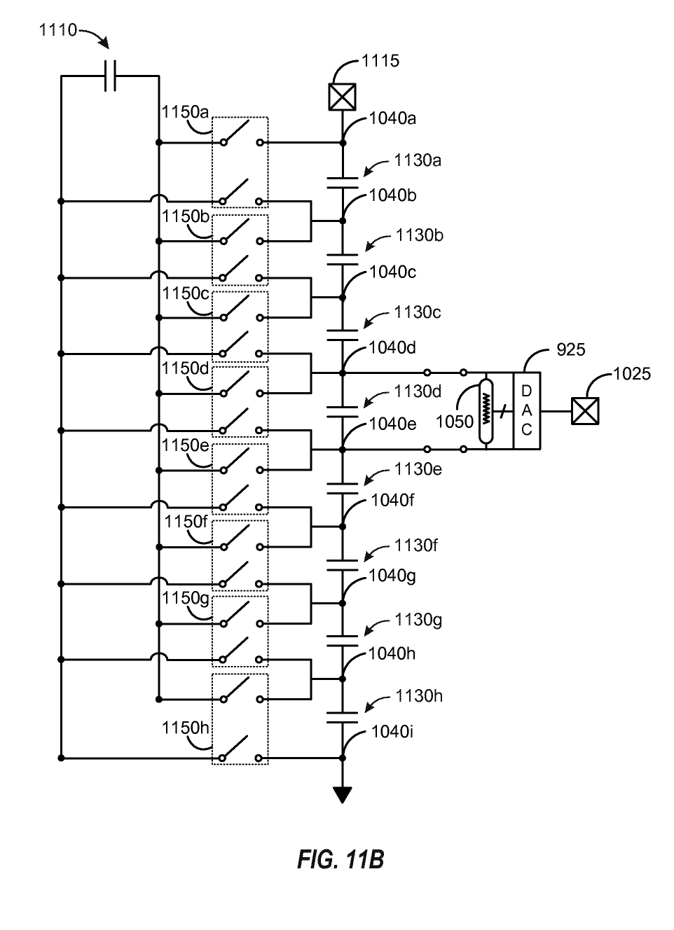

As another example, FIGS. 11A and 11B are circuit schematics of examples of simplified representations of FIGS. 10A and 10B. FIGS. 11A and 11B show DAC 925 “flying” to be coupled in parallel with particular capacitors 1130a-1130h based on control signals 1020a from data control unit 930. In FIGS. 11A and 11B, if voltage input 1115 is 8 V, then voltage sources 1040a-1040i range from 8 V to 0 V in 1 V increments such that voltage source 1040a is biased at 8 V and voltage source 1040b is biased at 7 V. In the example of FIG. 11A, data control unit 930 may receive data indicating that output 1025 is to provide 7.9375 V. Accordingly, data control unit 930 may provide control signals 1020a to indicate that a switch in high power supply switches 1010 and a switch in low power supply switches 1015 may be turned on to provide 8 V at node 1090 and 7 V at node 1030p (i.e., couple DAC 925 in parallel with capacitor 1130a in FIG. 11A). Since node 1090 is biased at 8 V and node 1030p is biased at 7 V, the voltages of nodes 1030a-1030p range from 7.9375 V to 7 V in 62.5 mV increments. Data control unit 930 may also provide control signals 1020b to DAC 925 to provide the voltage at node 1030a (i.e., 7.9375 V) to output 1025.

Next, data control unit 930 may receive data indicating that 4.875 V is to be provided at output 1025. Accordingly, data control unit 930 may provide control signals 1020a to indicate that a switch in high power supply switches 1010 and a switch in low power supply switches 1015 may be turned on to provide 5 V at node 1090 and 4 V at node 1030p (i.e., couple DAC 925 and string resistor ladder 1050 in parallel with capacitor 1130d in FIG. 11B). Since node 1090 is biased at 5 V and node 1030p is biased at 4 V, the voltages of nodes 1030a-1030p may range from 4.9375 V to 4 V in 62.5 mV increments. Data control unit 930 may also provide control signals 1020b to DAC 925 to provide the voltage at node 1030b (i.e., 4.875 V) to output 1025.

As another example, if 1.9375 V is to be provided at output 1025, then high power supply switches 1010 and low power supply switches 1010 may be turned on to bias node 1090 at 2 V and node 1030p at 1 V, respectively (i.e., couple DAC 925 in parallel with capacitor 1130g). Additionally, the voltage at node 1030a, biased at 1.9375 V, may be selected to be provided at output 1025 by DAC 925.

The preceding FIGS. 7-11B provide examples with eight capacitors 1130a-1130h providing nine voltage sources 1040a-1040i and string resistor ladder 1050 providing sixteen nodes 1030a-1030p as inputs for DAC 925 to select. However, the techniques and methods disclosed herein may be scaled to allow for different implementations. That is, the numbers of capacitors, voltage sources, control signals, and nodes may be different in other implementations. For example, eight capacitors 1130a-1130h may provide nine voltage sources 1040a-1040i, but string resistor ladder 1050 may provide thirty-two nodes rather than sixteen nodes as inputs for DAC 925 to select. Accordingly, 8-bit data may be received by data control unit 930. Three of the bits may still be used to provide control signals 1020a, but five bits may be used to provide control signals 1020b for DAC 925 to select one of the thirty-two inputs.

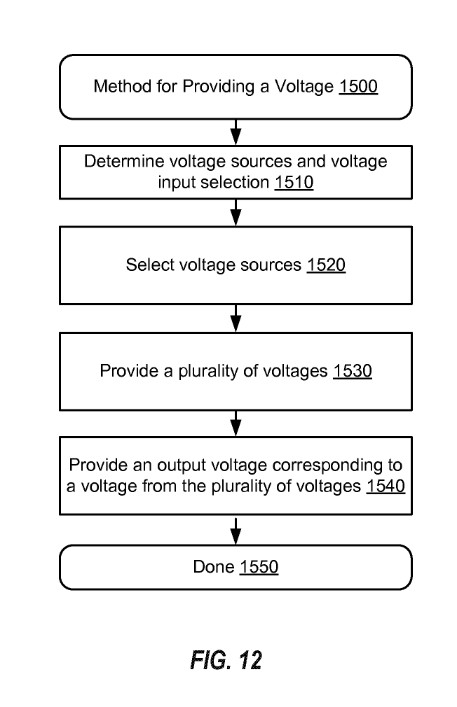

FIG. 12 is a flow diagram illustrating a method for providing a voltage. In method 1500, at block 1510, voltage sources and a DAC voltage input selection may be determined. For example, voltage sources 1040a-1040i to be selected by high power supply switches 1010 and low power supply switches 1015 may be determined. Additionally, one of nodes 1030a-1030p may be determined to provide a corresponding voltage at output 1025. At block 1520, the voltage sources may be selected. For example, data control unit 930 may provide control signals 1020a such that high power supply switches 1010 and low power supply switches 1015 select appropriate voltage sources 1040a-1040i. At block 1530, a plurality of voltages may be provided. For example, string resistor ladder 1050 may generate the plurality of voltages based on the selected voltage sources 1040a-1040i. At block 1540, an output voltage corresponding to a voltage from the plurality of voltages may be provided. For example, DAC 925 may provide a voltage at output 1025 corresponding to one of the plurality of voltages generated by string resistor ladder 1050 based on control signal 1020b provided by data control unit 930. The method is done at block 1550.

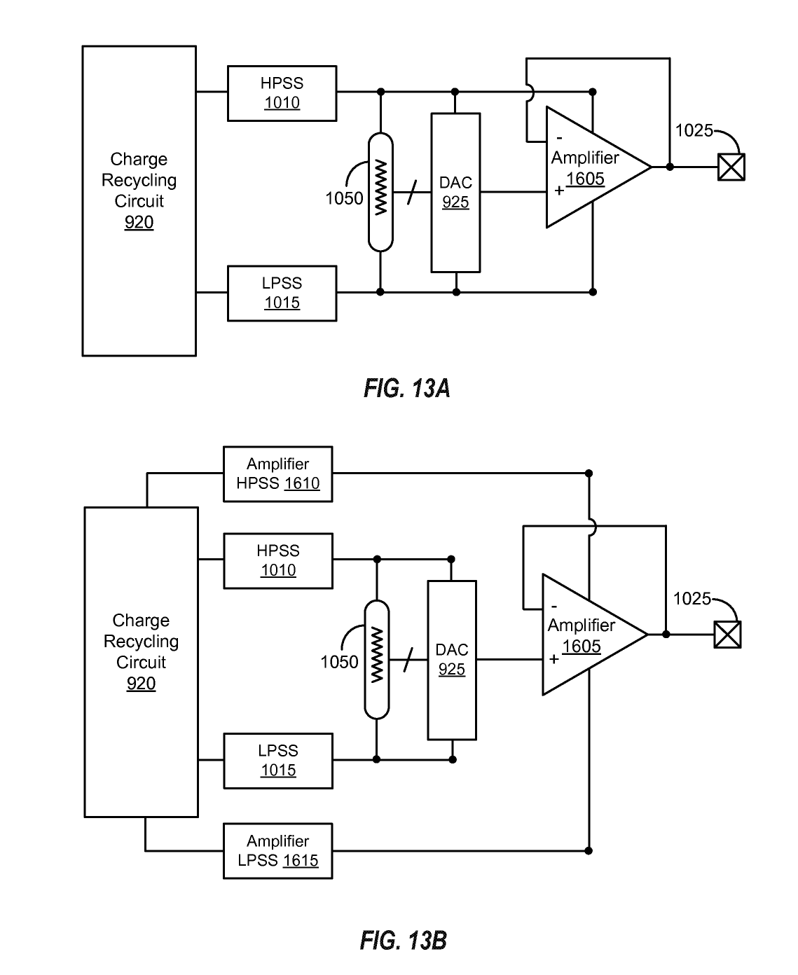

In some implementations, the output stage of a driver circuit may include an amplifier, coupled with the output of DAC 925, which may be used to provide faster performance for larger displays because the amplifier may be able to drive larger loads. The amplifier may also provide an output voltage, based on the output of DAC 925, to bias an electrode for a display unit in display array 30. FIGS. 13A and 13B are circuit schematics of examples of output stages of a driver circuit including an amplifier.

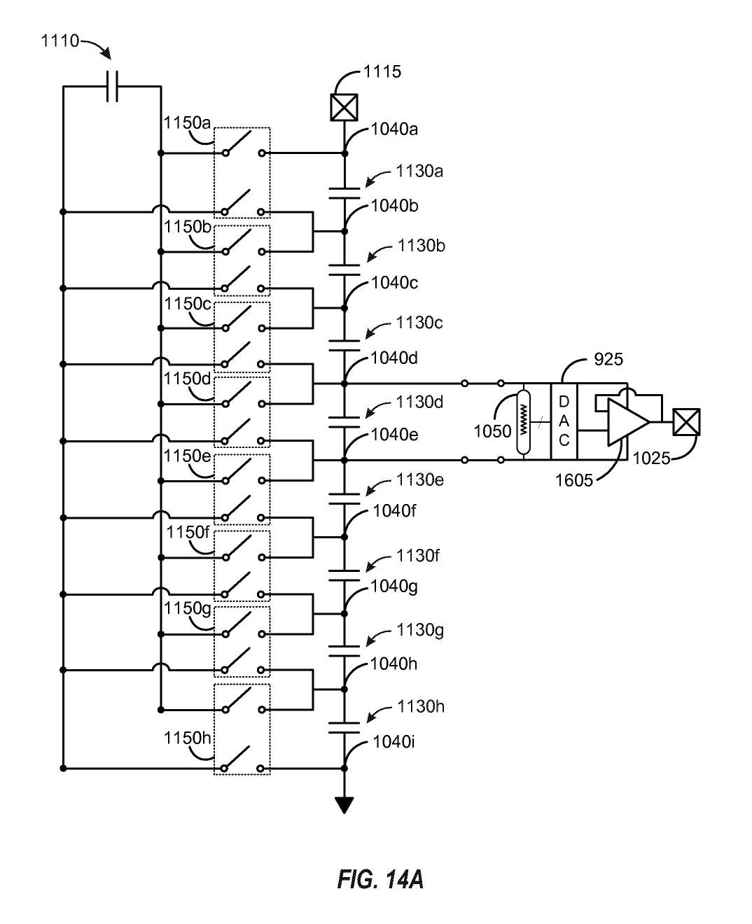

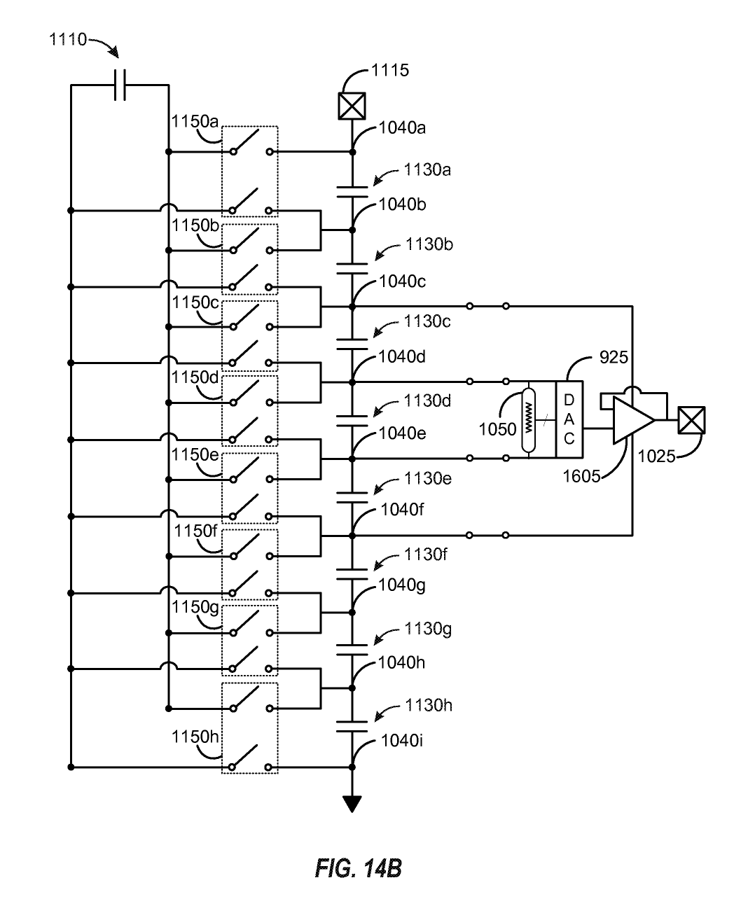

In FIG. 13A, amplifier 1605 may be an operational amplifier in a voltage follower configuration. The output of DAC 925 may be provided to the positive input of amplifier 1605. The output of amplifier 1605 may be provided to output 1025 and also provided to the negative input of amplifier 1605. The voltage sources providing power supplies of amplifier 1605 may be the same as the voltage sources selected among voltage sources 1040a-1040i by high power supply switches 1010 and low power supply switches 1015 for DAC 925 and string resistor ladder 1050. Accordingly, as DAC 925 “flies” between being coupled in parallel with different capacitors 1130a-1130h to use particular power supplies (by control signals 1020a provided by data control unit 930), amplifier 1605 may also coupled with the same power supplies. For example, FIG. 14A is a circuit schematic of an example of a simplified representation of FIG. 13A. In FIG. 14A, the power supplies for amplifier 1605 are the same as that of DAC 925.

By contrast, the implementation of FIG. 13B includes amplifier 1605 with its own set of amplifier high power supply switches 1610 and amplifier low power supply switches 1615. Amplifier high power supply switches 1610 and amplifier low power supply switches 1615 may also be controlled by control signals provided by data control unit 930. In FIG. 13B, amplifier high power supply switches 1610 and amplifier low power supply switches 1615 may select the same or different power supplies 1040a-1040i than high power supply switches 1010 and low power supply switches 1015 (i.e., the switches that provide voltages to nodes 1090 and 1030p of string resistor ladder 1050). For example, FIG. 14B is a circuit schematic of an example of a simplified representation of FIG. 13B. In FIG. 14B, amplifier high power supply switches 1610 and amplifier low power supply switches 1015 are “offset” from high power supply switches 1010 and low power supply switches 1015. If high power supply switches 1010 select voltage source 1040d providing 5 V, amplifier high power supply switches 1610 may select voltage source 1040c providing 6 V (i.e., a power supply providing a higher voltage than voltage source 1040d selected by high power supply switches 1010). If low power supply switches 1015 select voltage source 1040e providing 4 V, amplifier low power supply switches 1615 may select voltage source 1040f providing 3 V (i.e., a power supply providing a lower voltage than voltage source 1040f selected by low power supply switches 1015). In FIG. 14B, both amplifier high power supply switches 1610 and amplifier low power supply switches 1615 are offset by a single voltage source from high power supply switches 1010 and low power supply switches 1015. In other implementations, only one of amplifier high power supply switches 1610 and amplifier low power supply switches 1615 may be offset. For example, both low power supply switches 1015 and amplifier low power supply switches 1615 may select the same voltage source, but high power supply switches 1010 and amplifier high power supply switches 1610 may select different voltage sources 1040a-1040i. In some implementations, amplifier high power supply switches 1610 and/or amplifier low power supply switches 1615 may be offset by more than one voltage source.

Amplifier 1605 in FIGS. 13A and 17A may provide lower power requirements if it utilizes the same voltage sources 1040a-1040i as power supplies as DAC 925. However, amplifier 1605 having its power supplies (among voltage sources 1040a-1040i) selected by amplifier high power supply switches 1610 and amplifier low power supply switches 1615 to provide an offset with respect to the voltage sources selected by high power supply switches 1010 and low power supply switches 1015 may be used to reduce the load on capacitors 1130a-1130h. A high load can reduce the voltage at voltage sources 1040a-1040i and lower performance. In some implementations, charge recycling circuit 920 may provide voltage sources 1040a-1040i to a large number of DACS, say 200 DACs. If a large number of the 200 DACs are coupled in parallel to the same capacitor 1130a-1130h, the load on the capacitor may be high, and therefore, amplifier high power supply switches 1610 and amplifier low power supply switches 1615 for the 200 amplifiers coupled with the 200 DACs may select voltage sources 1040a-1040i at an offset from the voltage sources 1040a-1040i selected by high power supply switches 1010 and low power supply switches 1015 for the 200 DACs rather than increasing the load on the same capacitor.

In some implementations, data control unit 930 may analyze data indicating which of voltage sources 1040a-1040i are to be provided for each of the 200 DACs. If the number of DACs coupled in parallel with a particular capacitor exceeds a threshold number, then an offset is determined by data control unit 930 and the control signals for amplifier high power supply 1610 and amplifier low power supply 1615 are provided to reflect the offset. In some implementations, only a certain number of amplifier power supplies may be offset. For example, a threshold number may be reached when half of the amplifiers are coupled in parallel with the capacitor. Accordingly, a subset of amplifier high power supplies 1610 and amplifier low power supplies 1615 may be provided an offset rather than every amplifier.

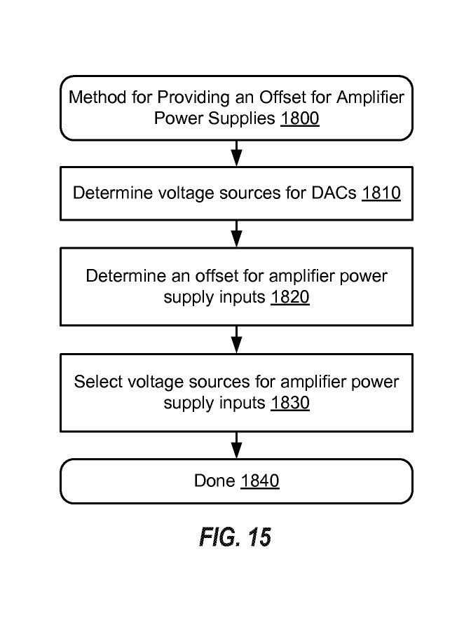

FIG. 15 is a flow diagram illustrating a method for providing an offset for amplifier power supplies. In method 1800, at block 1810, voltage sources for DACs may be determined. At block 1820, an offset for amplifier power supply inputs may be determined. At block 1830, the voltage sources for the amplifier power supply inputs may be selected to reflect the offset. The method is done at block 1840.

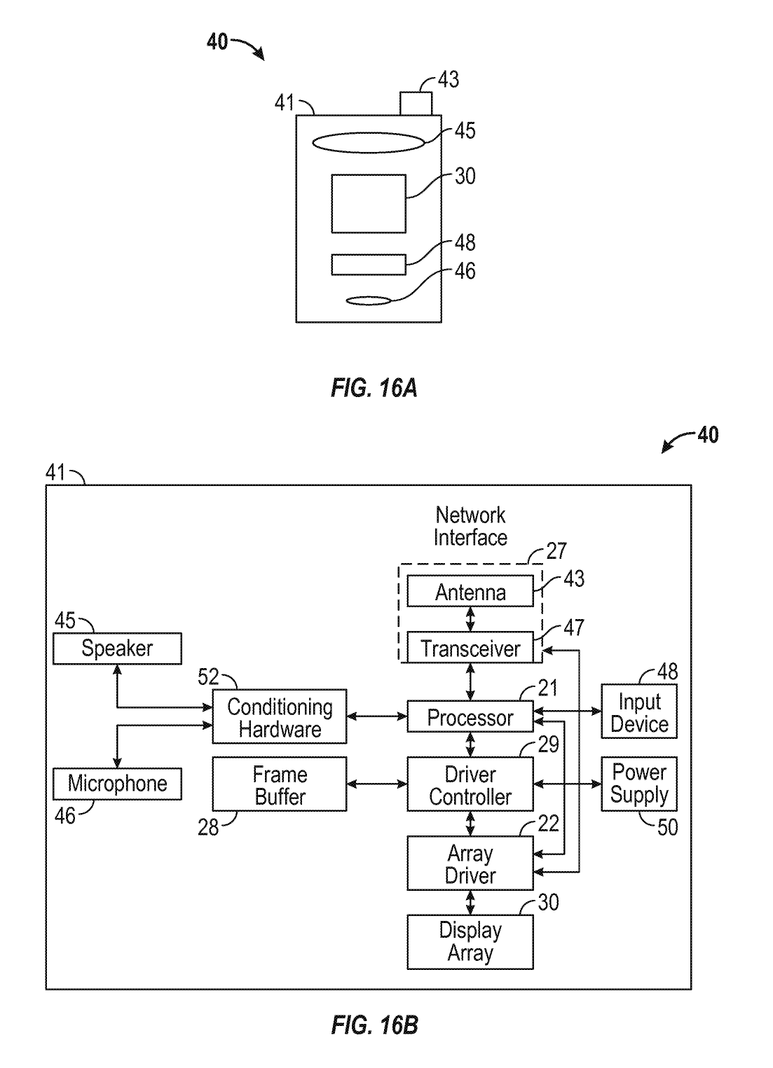

FIGS. 16A and 16B are system block diagrams illustrating a display device 40 that includes a plurality of IMOD display elements. The display device 40 can be, for example, a smart phone, a cellular or mobile telephone. However, the same components of the display device 40 or slight variations thereof are also illustrative of various types of display devices such as televisions, computers, tablets, e-readers, hand-held devices and portable media devices.

The display device 40 includes a housing 41, a display 30, an antenna 43, a speaker 45, an input device 48 and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an IMOD-based display, as described herein.

The components of the display device 40 are schematically illustrated in FIG. 16A. The display device 40 includes a housing 41 and can include additional components at least partially enclosed therein. For example, the display device 40 includes a network interface 27 that includes an antenna 43 which can be coupled to a transceiver 47. The network interface 27 may be a source for image data that could be displayed on the display device 40. Accordingly, the network interface 27 is one example of an image source module, but the processor 21 and the input device 48 also may serve as an image source module. The transceiver 47 is connected to a processor 21, which is connected to conditioning hardware 52. The conditioning hardware 52 may be configured to condition a signal (such as filter or otherwise manipulate a signal). The conditioning hardware 52 can be connected to a speaker 45 and a microphone 46. The processor 21 also can be connected to an input device 48 and a driver controller 29. The driver controller 29 can be coupled to a frame buffer 28, and to an array driver 22, which in turn can be coupled to a display array 30. One or more elements in the display device 40, including elements not specifically depicted in FIG. 16A, can be configured to function as a memory device and be configured to communicate with the processor 21. In some implementations, a power supply 50 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g, n, and further implementations thereof. In some other implementations, the antenna 43 transmits and receives RF signals according to the Bluetooth® standard. In the case of a cellular telephone, the antenna 43 can be designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1×EV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G, 4G or 5G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that can be readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of display elements.

In some implementations, the driver controller 29, the array driver 22, and the display array 30 are appropriate for any of the types of displays described herein. For example, the driver controller 29 can be a conventional display controller or a bi-stable display controller (such as an IMOD display element controller). Additionally, the array driver 22 can be a conventional driver or a bi-stable display driver (such as an IMOD display element driver). Moreover, the display array 30 can be a conventional display array or a bi-stable display array (such as a display including an array of IMOD display elements). In some implementations, the driver controller 29 can be integrated with the array driver 22. Such an implementation can be useful in highly integrated systems, for example, mobile phones, portable-electronic devices, watches or small-area displays.

In some implementations, the input device 48 can be configured to allow, for example, a user to control the operation of the display device 40. The input device 48 can include a keypad, such as a QWERTY keyboard or a telephone keypad, a button, a switch, a rocker, a touch-sensitive screen, a touch-sensitive screen integrated with the display array 30, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices. For example, the power supply 50 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

As used herein, a phrase referring to “at least one of” a list of items refers to any combination of those items, including single members. As an example, “at least one of: a, b, or c” is intended to cover: a, b, c, a-b, a-c, b-c, and a-b-c.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

If implemented in software, the functions may be stored on or transmitted over as one or more instructions or code on a computer-readable medium. The steps of a method or algorithm disclosed herein may be implemented in a processor-executable software module which may reside on a computer-readable medium. Computer-readable media includes both computer storage media and communication media including any medium that can be enabled to transfer a computer program from one place to another. A storage media may be any available media that may be accessed by a computer. By way of example, and not limitation, such computer-readable media may include RAM, ROM, EEPROM, CD-ROM or other optical disk storage, magnetic disk storage or other magnetic storage devices, or any other medium that may be used to store desired program code in the form of instructions or data structures and that may be accessed by a computer. Also, any connection can be properly termed a computer-readable medium. Disk and disc, as used herein, includes compact disc (CD), laser disc, optical disc, digital versatile disc (DVD), floppy disk, and blu-ray disc where disks usually reproduce data magnetically, while discs reproduce data optically with lasers. Combinations of the above also may be included within the scope of computer-readable media. Additionally, the operations of a method or algorithm may reside as one or any combination or set of codes and instructions on a machine readable medium and computer-readable medium, which may be incorporated into a computer program product.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of, e.g., an IMOD display element as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, a person having ordinary skill in the art will readily recognize that such operations need not be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

The circuits and techniques disclosed herein utilize examples of values (e.g., voltages, capacitances, etc.) that are provided for illustration purposes only. Other implementations may involve different values.

What is claimed is:

1. A circuit comprising:
a control unit having a first output and a second output;
a selector unit having an output and a control input, the control input of the selector unit coupled with the first output of the control circuit, the selector circuit capable of providing an output voltage at the output based on the control input of the selector circuit; and
a first voltage source selector unit having a control input, a first output, and a second output, the control input of the first voltage source selector unit coupled with the second output of the control unit, the first output of the first voltage source selector unit coupled with the first power supply input of the selector unit, the second output of the first voltage source selector unit coupled with the second power supply input of the selector unit, wherein the first voltage source selector unit is capable of selecting a first voltage source from a plurality of voltage sources to provide to the first output of the first voltage source selector unit and a second voltage source from the plurality of voltage sources to provide to the second output of the first voltage source selector unit based on the control input of the voltage selector.

2. The circuit of claim 1, wherein the selector unit includes:
a voltage divider with a first node and a second node, the first node coupled with the first voltage source, and the second node coupled with the second voltage source.

3. The circuit of claim 2, wherein the voltage divider is capable of providing a plurality of voltages based on a first voltage associated with the first voltage source and a second voltage associated with the second voltage source, wherein the output voltage provided by the output of the selector unit corresponds to a voltage in the plurality of voltages.

4. The circuit of claim 3, wherein the voltage divider is a resistor voltage divider including a plurality of resistors coupled in series to define nodes, the nodes of the resistor voltage divider capable of providing the plurality of voltages.

5. The circuit of claim 1, further comprising:
a capacitor voltage divider including a plurality of capacitors coupled in series to define nodes, the nodes capable of providing the plurality of voltage sources.

6. The circuit of claim 5, further comprising:
a storage capacitor coupled in parallel with one of the plurality of capacitors in the capacitor voltage divider.

7. The circuit of claim 1, further comprising:
an amplifier having a first input, a second input, an output, a first power supply input, and a second power supply input, the first input of the amplifier coupled with the output of the selector unit, the second input of the amplifier coupled with the output of the amplifier, the first power supply input of the amplifier coupled with the first voltage source, the second power supply input of the amplifier coupled with the second voltage source.

8. The circuit of claim 1, wherein the control unit includes a third output, and the circuit further comprises:
an amplifier having a first input, a second input, an output, a first power supply input, and a second power supply input, the first input of the amplifier coupled with the output of the selector unit, the second input of the amplifier coupled with the output of the amplifier; and
a second voltage source selector unit having a control input, a first output, and a second output, the control input of the second voltage source selector unit coupled with the third output of the control circuit, the first output of the second voltage source unit coupled with the first power supply input of the amplifier, the second output of the second voltage source selector unit coupled with the second power supply input of the amplifier, wherein the second voltage source selector unit is capable of providing a third voltage source to the first output and a fourth voltage source to the second output based on the control input of the voltage selector.

9. The circuit of claim 8, wherein the first voltage source is capable of providing a first voltage, the second voltage source is capable of providing a second voltage, the third voltage source is capable of providing a third voltage, and the fourth voltage source is capable of providing a fourth voltage, the third voltage being higher than the first voltage, and the fourth voltage being lower than the second voltage.

10. The circuit of claim 1, wherein the control unit is capable of analyzing data, wherein the control unit is capable of providing a first control signal to the control input of the selector unit based on the data, and wherein the control unit is capable of providing a second control signal to the control input of the first voltage selector unit based on the data.

11. The circuit of claim 10, wherein the data includes a first set of bits and a second set of bits, the first set of bits indicating the first voltage source and the second voltage source from the plurality of voltage sources are to be provided at the first output and the second output, respectively, of the first voltage source selector unit, the second set of bits indicating the output voltage to be provided at the output of the selector unit.

12. The circuit of claim 1, further comprising:
a display including a plurality of display units;
a processor that is capable of communicating with the display, the processor being configured to process image data; and
a memory device that is capable of communicating with the processor.

13. The circuit of claim 12, further comprising:
a driver circuit capable of sending at least one signal to the display; and
a controller capable of sending at least a portion of the image data to the driver circuit.

14. The circuit of claim 12, further comprising:
an image source module capable of sending the image data to the processor, wherein the image source module comprises at least one of a receiver, transceiver, and transmitter.

15. The circuit of claim 12, further comprising:
an input device capable of receiving input data and to communicate the input data to the processor.

16. A circuit comprising:
a control unit capable of receiving data and providing a voltage source determination and a voltage selection determination, the determinations based on the data;
a voltage source selector unit capable of selecting a first voltage source and a second voltage source from a plurality of voltage sources based on the voltage source determination;
a voltage divider capable of providing a plurality of voltages based on the first voltage source and the second voltage source; and
a digital-to-analog converter (DAC) capable of providing an output voltage corresponding to one of the plurality of voltages based on the voltage selection determination.

17. The circuit of claim 16, further comprising:
a capacitor voltage divider including a plurality of capacitors coupled in series to define nodes, the nodes capable of providing the plurality of voltage sources; and
a storage capacitor coupled in parallel with one of the plurality of capacitors in the capacitor voltage divider.

18. The circuit of claim 16, further comprising:
an amplifier capable of providing an output voltage based on the output voltage of the DAC.

19. The circuit of claim 18, wherein the control unit is capable of providing an amplifier voltage source determination based on the data.

20. The circuit of claim 16, wherein the output voltage is provided to a display unit.

21. A method comprising:
determining a first voltage source, a second voltage source, and a voltage input selection, the determination of the first voltage source, the second voltage source, and the voltage input selection based on data indicating a voltage;
selecting the first voltage source and the second voltage source;
providing a plurality of voltages based on the first voltage source and the second voltage source; and
providing an output voltage corresponding to one of the plurality of voltages based on the voltage input selection.

22. The method of claim 21, wherein the plurality of voltages based on the first voltage source and the second voltage source is provided to a digital-to-analog converter (DAC).

23. The method of claim 22, wherein the first voltage source and the second voltage source are further provided to an amplifier.

24. The method of claim 21, the method further comprising:
determining an offset for voltage sources for an amplifier, the offset indicating a difference between the voltage sources for the amplifier and the first voltage source and the second voltage source;
selecting a third voltage source and a fourth voltage source based on the offset; and
providing the third voltage source and the fourth voltage source to the amplifier.
